(19) United States
(12) Patent Application Publication
(10) Pub. No.: US 2025/0356072 A1
(43) Pub. Date: Nov. 20, 2025

(54) INFORMATION PROCESSING METHOD, NON-TRANSITORY COMPUTER-READABLE RECORDING MEDIUM, AND INFORMATION PROCESSING TERMINAL

(71) Applicant: Panasonic Intellectual Property Management Co., Ltd., Osaka (JP)

(72) Inventors: Hirokazu KAWAMOTO, Osaka (JP); Eiichi Muramoto, Kanagawa (JP)

(21) Appl. No.: 19/285,377

(22) Filed: Jul. 30, 2025

Related U.S. Application Data
(63) Continuation of application No. PCT/JP2023/045756, filed on Dec. 20, 2023.
(60) Provisional application No. 63/445,817, filed on Feb. 15, 2023.

(51) Int. Cl. G06F 30/15

(52) U.S. Cl. CPC G06F 30/15

(57) ABSTRACT

An information processing method is an information processing method to be executed by a computer and includes: executing, according to an operation parameter of a mobile body that carries a person or a delivery item, a simulation of movement of the mobile body and demand for transfer of the person or the delivery item; calculating, based on an execution result of the simulation, a transition of a state of an object in the simulation; determining, based on the transition, whether a constraint condition is satisfied; and outputting, when the constraint condition is satisfied, an evaluation result of evaluating the execution result of the simulation using at least one of a safety index, an economic rationality index, or a convenience index each pertaining to at least an operation of the mobile body.

### CROSS REFERENCE TO RELATED APPLICATIONS

This is a continuation application of PCT International Application No. PCT/JP2023/045756 filed on Dec. 20, 2023, designating the United States of America, which is based on and claims priority of U.S. Provisional Patent Application No. 63/445,817 filed on Feb. 15, 2023. The entire disclosures of the above-identified applications, including the specifications, drawings and claims are incorporated herein by reference in their entirety.

### FIELD

The present disclosure relates to an information processing method, a non-transitory computer-readable recording medium, and an information processing terminal for executing a simulation of a mobility service.

### BACKGROUND

In recent years, along with a change in the environment surrounding the markets as represented by connected autonomous shared electric (CASE), there has been an increasing demand for mobility services. At the same time, there are a wide variety of elements configuring a mobility service (service factors). In order to optimize the mobility service, the mobility service needs to be designed and evaluated beforehand.

According to Non Patent Literature (NPL) 1, a simulation is utilized in the design and the evaluation of a mobility service for introducing and improving the mobility service.

Patent Literature (PTL) 1 discloses automatically generating an operational plan that increases the number of autonomous moving apparatuses operable within a given space in the same time period.

### CITATION LIST

### Non Patent Literature

NPL 1: Masayuki YAMAMOTO, et al., “Simulation Analysis of Autonomous Ride-Sharing Service in City Area,” [online], [searched on Jun. 30, 2023], Internet <URL: https://www.denso.com/jp/ja/-/media/global/business/innovation/review/24/24-doc-07-paper-02.pdf>

### Patent Literature

PTL 1: Japanese Unexamined Patent Application Publication No. 2022-189396

### SUMMARY

### Technical Problem

However, NPL 1 and PTL 1 have such a problem that it is difficult to execute an efficient simulation that takes into account a constraint condition.

Hence, the present disclosure provides an information processing method and the like that facilitate the execution of an efficient simulation that takes into account a constraint condition.

### Solution to Problem

An information processing method according to the present disclosure is an information processing method to be executed by a computer, the information processing method including: executing, according to an operation parameter of a mobile body that carries a person or a delivery item, a simulation of movement of the mobile body and demand for transfer of the person or the delivery item; calculating, based on an execution result of the simulation, a transition of a state of an object in the simulation; determining, based on the transition, whether a constraint condition is satisfied; and outputting, when the constraint condition is satisfied, an evaluation result of evaluating the execution result of the simulation using at least one of a safety index, an economic rationality index, or a convenience index each pertaining to at least an operation of the mobile body.

Note that these general or specific aspects may be implemented using a system, a method, an integrated circuit, a computer program, or a computer-readable recording medium such as a compact disc read-only memory (CD-ROM), or any combination of systems, methods, integrated circuits, computer programs, and recording media.

### Advantageous Effects

The information processing method and the like according to an aspect of the present disclosure facilitate the execution of an efficient simulation that takes into account a constraint condition.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a block diagram illustrating an example of an information processing system according to an embodiment.

FIG. 2 is a diagram showing an example of a temporal logic expression used to determine whether a constraint condition is satisfied.

FIG. 3 is an explanatory diagram of determination using a temporal logic expression.

FIG. 4 is an explanatory diagram of a first condition.

FIG. 5 is an explanatory diagram of a second condition.

FIG. 6 is an explanatory diagram of a third condition.

FIG. 7 is an explanatory diagram of a fourth condition.

FIG. 8 is an explanatory diagram of a fifth condition.

FIG. 9 is an explanatory diagram of a sixth condition.

FIG. 10 is an explanatory diagram of a seventh condition.

FIG. 11 is an explanatory diagram of an eighth condition.

FIG. 12 is an explanatory diagram of a ninth condition.

FIG. 13 is a flowchart illustrating a basic operation example of an information processing system according to an embodiment.

FIG. 14 is a diagram illustrating an example of a screen showing a correlation between transitions of the state of an object and a constraint violation degree.

FIG. 15 is a diagram illustrating an example of an input value setting screen.

FIG. 16 is a diagram illustrating an example of a screen showing the status of whether a constraint condition is met.

FIG. 17 is a flowchart illustrating a first operation example of an information processing system according to an embodiment.

FIG. 18 is a diagram illustrating an example of a constraint condition setting screen.

FIG. 19 is a flowchart illustrating a specific example of a first operation example of an information processing system according to an embodiment.

FIG. 20 is a flowchart illustrating another specific example of a first operation example of an information processing system according to an embodiment.

FIG. 21 is a flowchart illustrating a second operation example of an information processing system according to an embodiment.

FIG. 22 is a diagram illustrating an example of a screen for verifying whether a constraint condition is valid.

FIG. 23 is a flowchart illustrating a third operation example of an information processing system according to an embodiment.

FIG. 24 is a flowchart illustrating a specific example of a third operation example of an information processing system according to an embodiment.

FIG. 25 is a flowchart illustrating a fourth operation example of an information processing system according to an embodiment.

FIG. 26 is a flowchart illustrating a specific example of a fourth operation example of an information processing system according to an embodiment.

FIG. 27 is a flowchart illustrating a fifth operation example of an information processing system according to an embodiment.

FIG. 28 is a flowchart illustrating a specific example of a fifth operation example of an information processing system according to an embodiment.

### DESCRIPTION OF EMBODIMENTS

An information processing method according to a first aspect of the present disclosure is an information processing method to be executed by a computer, and includes: executing, according to an operation parameter of a mobile body that carries a person or a delivery item, a simulation of movement of the mobile body and demand for transfer of the person or the delivery item; calculating, based on an execution result of the simulation, a transition of a state of an object in the simulation; determining, based on the transition, whether a constraint condition is satisfied; and outputting, when the constraint condition is satisfied, an evaluation result of evaluating the execution result of the simulation using at least one of a safety index, an economic rationality index, or a convenience index each pertaining to at least an operation of the mobile body.

Accordingly, it is possible to determine whether the constraint condition is satisfied with consideration given to not only temporal changes but also spatial changes of the object, thus bringing about such an advantage that an efficient simulation that takes into account the constraint condition is easily executed.

Also, for example, an information processing method according to a second aspect of the present disclosure is the information processing method according to the first aspect, in which the constraint condition includes a plurality of conditions, and the determining of whether the constraint condition is satisfied is performed based on one function that refers to the state of the object differently for each of the plurality of conditions.

Accordingly, it is possible to execute the process of the determination to determine whether the constraint condition is satisfied, in a uniform and systematic manner, thus bringing about such an advantage that the process of the determination is easy to describe and is less likely to include a description error even when the constraint condition includes many conditions.

Also, for example, an information processing method according to a third aspect of the present disclosure is the information processing method according to the second aspect, in which the one function is described using a temporal logic expression.

Accordingly, it is possible to execute the process of the determination to determine whether the constraint condition is satisfied, in a uniform and systematic manner, thus bringing about such an advantage that the process of the determination is easy to describe and is less likely to include a description error even when the constraint condition includes many conditions.

Also, for example, an information processing method according to a fourth aspect of the present disclosure is the information processing method according to any one of the first through third aspects, in which the constraint condition includes a condition regarding movement or stop of the mobile body in a predetermined zone or during a predetermined time period.

Accordingly, the simulation is executed such that the mobile body complies with a predetermined rule regarding the movement or stop, thus bringing about such an advantage that an execution result of the simulation that prevents the mobile body from violating the predetermined rule is easily obtained.

Also, for example, an information processing method according to a fifth aspect of the present disclosure is the information processing method according to any one of the first through fourth aspects, in which the constraint condition includes a condition regarding a movement duration of the mobile body.

Accordingly, the simulation is executed such that the mobile body complies with a predetermined rule regarding the movement duration, thus bringing about such an advantage that an execution result of the simulation that prevents the mobile body from violating the predetermined rule is easily obtained.

Also, for example, an information processing method according to a sixth aspect of the present disclosure is the information processing method according to any one of the first through fifth aspects, in which the constraint condition includes a condition regarding movement of the mobile body with respect to a base for the mobile body.

Accordingly, the simulation is executed such that the mobile body complies with a predetermined rule regarding the movement of with respect to the base, thus bringing about such an advantage that an execution result of the simulation that prevents the mobile body from violating the predetermined rule is easily obtained.

Also, for example, an information processing method according to a seventh aspect of the present disclosure is the information processing method according to any one of the first through sixth aspects, in which the constraint condition includes a condition regarding an operator that remotely controls the mobile body.

Accordingly, the simulation is executed such that the operator complies with a predetermined rule regarding the operator, thus bringing about such an advantage that an execution result of the simulation that prevents the operator from violating the predetermined rule is easily obtained.

Also, for example, an information processing method according to an eighth aspect of the present disclosure is the information processing method according to any one of the first through seventh aspects, in which the constraint condition includes a condition regarding a stock of the delivery item carried by the mobile body.

Accordingly, the simulation is executed such that the mobile body complies with a predetermined rule regarding the stock, thus bringing about such an advantage that an execution result of the simulation that prevents the mobile body from violating the predetermined rule is easily obtained.

Also, for example, an information processing method according to a ninth aspect of the present disclosure is the information processing method according to any one of the first through eighth aspects, further including: obtaining, before the executing of the simulation, the constraint condition specified by a user.

Accordingly, there is brought about such an advantage that the simulation that takes into account the constraint condition desired by the user, rather than a preset constraint condition, can be executed.

Also, for example, an information processing method according to a tenth aspect of the present disclosure is the information processing method according to any one of the first through ninth aspects, further including: loosening at least part of the constraint condition when the constraint condition is not satisfied.

Accordingly, the at least part of the constraint condition is loosened, thus bringing about such an advantage that the constraint condition is easily satisfied in the next simulation.

Also, for example, an information processing method according to an eleventh aspect of the present disclosure is the information processing method according to any one of the first through tenth aspects, further including: outputting a degree of violation of the constraint condition when the constraint condition is not satisfied.

Accordingly, there is brought about such an advantage that it becomes easier for the system or the user to determine how much the constraint condition should be loosened in the next simulation, by referring to the degree of violation of the constraint condition.

Also, for example, an information processing method according to a twelfth aspect of the present disclosure is the information processing method according to any one of the first through eleventh aspects, further including: tightening at least part of the constraint condition when a predetermined condition is not satisfied by the evaluation result.

Accordingly, the at least part of the constraint condition is tightened, thus bringing about such an advantage that the evaluation result easily satisfies the predetermined condition in the next simulation.

Also, for example, an information processing method according to a thirteenth aspect of the present disclosure is the information processing method according to any one of the first through twelfth aspects, further including: outputting a degree of leeway of the constraint condition when a predetermined condition is not satisfied by the evaluation result.

Accordingly, there is brought about such an advantage that it becomes easier for the system or the user to determine how much the constraint condition should be tightened in the next simulation, by referring to the degree of leeway of the constraint condition.

Also, for example, a program according to a fourteenth aspect of the present disclosure causes a computer to execute the information processing method according to any one of the first through thirteenth aspects.

Accordingly, it is possible to determine whether the constraint condition is satisfied with consideration given to not only temporal changes but also spatial changes of the object, thus bringing about such an advantage that an efficient simulation that takes into account the constraint condition is easily executed.

Also, for example, an information processing terminal according to a fifteenth aspect of the present disclosure includes an input receiver and an outputter. The input receiver receives an input of the operation parameter of the mobile body. The outputter outputs the execution result of the information processing method according to any one of the first through thirteenth aspects executed based on the operation parameter of the mobile body received by the input receiver. The outputter outputs the evaluation result as the execution result when the constraint condition is satisfied.

Accordingly, it is possible to determine whether the constraint condition is satisfied with consideration given to not only temporal changes but also spatial changes of the object, thus bringing about such an advantage that the user easily conducts preliminary investigations of the mobility service based on the evaluation result of evaluating the execution result of the efficient simulation that takes into account the constraint condition.

Hereinafter, certain exemplary embodiments will be specifically described with reference to the accompanying drawings.

Note that each of the exemplary embodiments described below shows a general or specific example. The numerical values, shapes, materials, constituent elements, the arrangement and connection of the constituent elements, steps, the processing order of the steps etc. shown in the following exemplary embodiments are mere examples and therefore do not limit the present disclosure.

### EMBODIMENT

Hereinafter, an information processing system and an information processing method according to an embodiment will be described.

### 1. Configuration

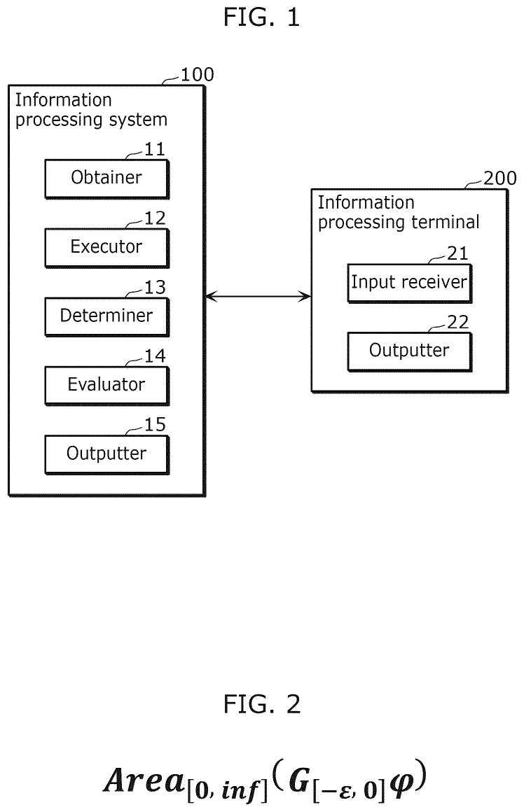

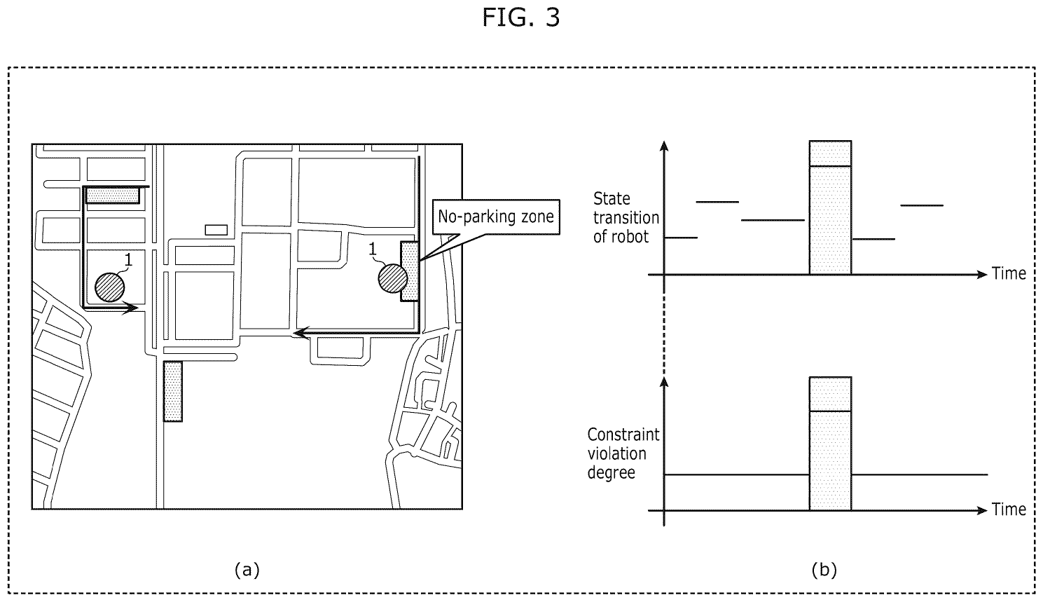

FIG. 1 is a block diagram illustrating an example of information processing system 100 according to the embodiment. Information processing system 100 is a system that performs a simulation of a service using mobile body 1 that carries a person or a delivery item (see FIG. 3), that is, a mobility service. The simulation is a simulation of the movement of mobile body 1 and the demand for the transfer of the person or the delivery item. Note that the simulation may include a simulation of avoiding a collision (determining a collision) between mobile body 1 and an object. The mobility service includes a service of delivering a delivery item to a client, such as a home delivery service or food delivery. The mobility service also includes, for example, a service of transporting a person to a destination.

Mobile body 1 is, for example, an autonomous mobile robot. However, mobile body 1 may be a vehicle such as an automobile or a motorcycle or may be a mobile body other than a vehicle, such as an aircraft or a watercraft. Mobile body 1 may be manually driven or may be semi-automatically driven or fully-automatically driven. In the following description, mobile body 1 is assumed to be an autonomous mobile robot unless otherwise specified.

Information processing system 100 is an example of a computer that executes the information processing method. The constituent elements constituting information processing system 100 may be provided in one housing or may be disposed in a distributed manner. In the case where the constituent elements constituting information processing system 100 are disposed in a distributed manner, the information processing method may be executed by a plurality of computers.

Information processing system 100 is implemented with, for example, a personal computer, a server device, or the like. In the embodiment, information processing system 100 is implemented with a server device. In the embodiment, at least part of information necessary for a simulation executed by information processing system 100 is obtained from information processing terminal 200 held by a user. The user herein is a user of information processing system 100. For example, the user is a designer of the mobility service.

Information processing terminal 200 is, for example, a mobile terminal such as a smartphone or a tablet. Information processing terminal 200 includes input receiver 21 and outputter 22. Input receiver 21 receives an operative input made by the user with an input device such as a mouse or a keyboard or an operative input made by the user with a finger of the user. Outputter 22 is, for example, a liquid crystal display. Outputter 22 displays an input screen or the like that is used to input initial values, input values, and the like described later. In the embodiment, outputter 22 is constituted by a touch panel display. Therefore, in the embodiment, outputter 22 also serves as input receiver 21.

Note that information processing system 100 may be installed in information processing terminal 200 as a function of information processing terminal 200. Conversely, information processing terminal 200 may be installed in information processing system 100 as a function of information processing system 100. That is, information processing system 100 and information processing terminal 200 may be implemented integrally as one device.

As illustrated in FIG. 1, information processing system 100 includes obtainer 11, executor 12, determiner 13, evaluator 14, and outputter 15. Information processing system 100 is a computer including a processor, a communication interface, a memory, and the like. The memory is a read only memory (ROM), and a random access memory (RAM), or the like. The memory is capable of storing a program to be executed by the processor. Obtainer 11, executor 12, determiner 13, evaluator 14, and outputter 15 are implemented with the processor executing the program stored in the memory, the communication interface, and the like.

Obtainer 11 obtains operation parameters of mobile body 1, which are various parameters to be used in a simulation executed by executor 12. In the embodiment, obtainer 11 obtains, as the operation parameters of mobile body 1, information input by the user making initial setting on input receiver 21 of information processing terminal 200. In the initial setting, the user makes the setting of an environment where the mobility service is performed, the setting of a demand created in the set environment, the setting of elements that configure the mobility service (service factors), and the like. More specifically, in the initial setting, the user makes the setting of a target area where the mobility service is to be performed, the setting of variables, the setting of constraint conditions, the setting of objective functions, and the like.

The setting of the target area is made by the user inputting, for example, map data on the target area, data indicating a traffic volume of mobile body 1 and traffic participants in the target area, data indicating demands made in the target area, and the like. The traffic participants include, for example, pedestrians and vehicles such as bicycles or automobiles. The demands are the number of requests for transportation of a person or requests for delivery of a delivery item in the target area from the user of the mobility service. The settings of the demands are made by the user inputting, for example, existing service usage data in the target area.

The setting of the variables is made by the user inputting data indicating, for example, the type of mobile body 1, the movement route of mobile body 1, an operation time period of mobile body 1, the riding capacity of mobile body 1, the speed of mobile body 1, the number of mobile bodies 1, the performance of a sensor installed on mobile body 1, the performance of a brake installed on mobile body 1, the acceleration performance of mobile body 1, the degree of the redundancy of the system, the remote monitoring of mobile body 1, the remote control of mobile body 1, and the like.

The setting of the constraint condition is made by the user inputting data indicating, for example, a place that mobile body 1 is permitted (or forbidden) to enter in the target area, and a place where the moving speed of mobile body 1 in the target area is restricted, and the speed limit of mobile body 1 in the place, or the like. The constraint condition will be described in detail later in the section [2. Constraint condition].

The setting of the objective function is made by the user inputting data indicating, for example, minimizing an initial cost necessary to introduce the mobility service, minimizing an operational cost necessary to operate the mobility service, and maximizing the number of transportations or the number of deliveries, and the like.

Note that the user may make all of the initial settings mentioned above or may make only part of the initial settings. In the latter case, for the parameters that the user does not input, in the initial setting, default values that are stored in advance in information processing system 100 may be assigned, for example.

Executor 12 executes a simulation of the movement of mobile body 1 and a demand for the transfer of a person or a delivery item according to the operation parameters of mobile body 1 obtained by obtainer 11. Executor 12 executes a simulation of the movements of one or more mobile bodies 1 and one or more traffic participants according to the traffic volume, the demands, the variables, the constraint condition, the objective function, and the like of the target area that are set in the initial setting. Here, in the case where the number of objective functions is one, one execution result of the simulation is obtained by executor 12 executing the simulation in such a manner as to calculate an optimal solution of the objective function. In contrast, in the case where the number of objective functions is more than one, a plurality of execution results of the simulation are obtained by executor 12 executing the simulation in such a manner as to calculate a plurality of Pareto optimal solutions.

Based on the execution result of the simulation by executor 12, determiner 13 calculates transitions of the state of an object in the simulation. Here, the object is an entity of which the state is defined in a simulation of, for example, mobile body 1 or an operator who remotely monitors or remotely controls mobile body 1, and can transition in the simulation. In the simulation, determiner 13 calculates transitions of the state of mobile body 1 as the object, for example, whether mobile body 1 is moving, stationary, or present at a predetermined place. In the simulation, determiner 13 also calculates transitions of the state of the operator as the object, for example, whether the operator is remotely controlling mobile body 1.

Determiner 13 also determines, based on the calculated transitions, whether the constraint condition is satisfied. In the simulation, determiner 13 determines, for example, whether transitions of the state of mobile body 1 as the object satisfy the constraint condition. In the simulation, determiner 13 also determines, for example, whether transitions of the state of the operator as the object satisfy the constraint condition. The process of determining whether the constraint condition is satisfied will be described in detail later in the section [2. Constraint condition].

When determiner 13 determines that the constraint condition is satisfied, evaluator 14 evaluates the execution result of the simulation by executor 12. In the embodiment, evaluator 14 evaluates the execution result of the simulation using three indices including a safety (Risk) index pertaining to the operation of mobile body 1, an economic rationality (Cost) index pertaining to the operation of mobile body 1, and a convenience (Value) index pertaining to the operation of mobile body 1. Note that it suffices if evaluator 14 evaluates the execution result of the simulation using at least one of the above three indices.

The safety index is an index that comprehensively indicates, for example, the risk of a proximity of mobile body 1 to a traffic participant during the operation of the mobility service. The economic rationality index is an index that comprehensively indicates, for example, the price and the fuel expenses of mobile body 1 and the cost necessary for the operation of the mobility service. The convenience index is an index that comprehensively indicates, for example, the number of transportations of persons that can be provided by the mobility service per day or the number of deliveries of delivery items that can be provided by the mobility service per day.

Here, calculation examples of each of the evaluation of the safety index, the evaluation of the economic rationality index, and the evaluation of the convenience index will be described. Note that each of the evaluation of the safety index, the evaluation of the economic rationality index, and the evaluation of the convenience index may be calculated by methods other than the calculation examples shown below.

For example, the evaluation of the safety index is calculated by calculating, for each mobile body 1, a degree of danger of collision based on a degree of proximity in the distance between mobile body 1 and a traffic participant and summing up the degree of danger of collision calculated for each mobile body 1.

Specifically, the evaluation of the safety index is calculated by, for example, Expression (1) shown below. In Expression (1), “i” denotes mobile body 1, “j” denotes a predetermined range with respect to the position of mobile body 1, “Wⱼ” denotes a weighting coefficient of a degree of danger according to the size of the predetermined range, and “nᵢⱼ” denotes the number of proximities between mobile body 1 and a traffic participant in the predetermined range. In other words, the weighting coefficient of the degree of danger is the severity of an injury.

$$\begin{matrix}[ Math . 1 ] & \\ {\sum }_{i} {\sum }_{j} {w}_{j} \times {n}_{ij} & ( 1 )\end{matrix}$$

For example, assuming that given mobile body 1 is denoted by “i=1,” when a pedestrian (a traffic participant) corresponding to “j=1” enters the predetermined range with respect to given mobile body 1, “n₁₁” is incremented by 1. When a bicycle (another traffic participant) corresponding to “j=2” enters the predetermined range, “n₁₂” is incremented by 1.

Note that the degree of danger of collision may be calculated by being further multiplied by, for example, a weighting coefficient according to the type of a traffic participant (an automobile, a motorcycle, a bicycle, or a pedestrian). The degree of danger of collision may be calculated by being further multiplied by, for example, a weighting coefficient according to the speed of a traffic participant.

The evaluation of the economic rationality index is calculated by, for example, Expression (2) shown below. In Expression (2), “i” denotes mobile body 1, “j” denotes personnel involved in the operation of mobile body 1, “CVᵢ” denotes a cost associated with preparing mobile body 1 necessary for the operation of the mobility service, “CFᵢ” denotes the cost of fuel according to a distance traveled by mobile body 1 during the operation of the mobility service, and “CHⱼ” denotes the personnel cost of the personnel involved in the operation of mobile body 1.

$$\begin{matrix}[ Math . 2 ] & \\ {\sum }_{i} {CV}_{i} + {\sum }_{i} {CF}_{i} + {\sum }_{j} {CH}_{j} & ( 2 )\end{matrix}$$

The evaluation of the convenience index is calculated by any one of Expressions (3) and (4) shown below in the case where the mobility service is, for example, a service of delivering a delivery item to a client, such as a home delivery service. In Expression (3), “i” denotes mobile body 1 and “VTᵢ” denotes the number of deliveries of delivery items during a given time period. In Expression (4), “j” denotes a delivery of a delivery item, “RTⱼ” denotes a time point at which the delivery is actually completed, and “PTⱼ” denotes a planned time point of the completion of the delivery. That is, Expression (4) represents the total of delay durations in the deliveries of delivery items.

$$\begin{matrix}[ Math . 3 ] & \\ {\sum }_{i} {VT}_{i} & ( 3 )\end{matrix}$$

$${\sum }_{j} {RT}_{j} - {PT}_{j} \qquad ( 4 )$$

The evaluation of the convenience index is calculated by Expression (5) shown below in the case where the mobility service is, for example, a mobile vending service of articles. In Expression (5), “k” denotes the sale of an article, and “Sₖ” denotes a revenue from the sale. That is, Expression (5) represents the total revenue from the sales of articles during operating hours.

$$\begin{matrix}[ Math . 4 ] & \\ {\sum }_{k} {S}_{k} & ( 5 )\end{matrix}$$

Outputter 15 outputs the evaluation result of the evaluation by evaluator 14. In the embodiment, evaluator 14 evaluates the execution result of the simulation by executor 12, using each of the safety index, the economic rationality index, and the convenience index pertaining to the operation of mobile body 1, as mentioned above. Therefore, in the embodiment, the evaluation result includes the results of evaluations using each of the safety index, the economic rationality index, and the convenience index pertaining to the operation of mobile body 1.

Note that, when determiner 13 determines that the constraint condition is not satisfied, outputter 15 may output a determination result indicating that the constraint condition is not satisfied.

### 2. Constraint Condition

Next, the constraint condition in the simulation executed by information processing system 100 according to the embodiment will be described. In the embodiment, the constraint condition includes a plurality of conditions, such as a first condition to a ninth condition described later. In the embodiment, determiner 13 performs the process of determining whether the constraint condition is satisfied based on one function that refers to the state of an object differently for each of the plurality of conditions. In particular, in the embodiment, the function is described using a temporal logic expression as shown in FIG. 2. That is, in the embodiment, determiner 13 determines, using the temporal logic expression, whether the constraint condition is satisfied.

FIG. 2 is a diagram showing an example of the temporal logic expression used to determine whether the constraint condition is satisfied. In FIG. 2, “Area” represents a function of always (“G”) accumulating (adding) a penalty value while the modality (“φ”) of an object deviates an allowable range (−ε, 0) during the entire period of the simulation ([0, inf]). In the embodiment, the constraint condition includes the plurality of conditions as mentioned above, and the process of determining whether each of the conditions is satisfied can be described with the above one temporal logic expression. Specifically, in the embodiment, by changing “ε,” “φ” and the penalty value in the above one temporal logic expression for each condition, it is possible to execute a process that includes the determination of whether the constraint condition is satisfied and that accumulates the penalty value in a uniform and systematic manner.

Here, an advantage of using the temporal logic expression to determine whether the constraint condition is satisfied will be described with reference to FIG. 3. FIG. 3 is an explanatory diagram of a method for the determination using the temporal logic expression. In FIG. 3, (a) is an explanatory diagram of an example of a determination method in a comparative example, and (b) is an explanatory diagram of an example of the method for the determination using the temporal logic expression. In FIG. 3, (a) and (b) each illustrate an example of determining whether such a constraint condition that a long time stop of mobile body 1 in a no-parking zone is forbidden ([−ε, 0]φ) is satisfied.

In FIG. 3, (a) illustrates a map of the target area, the place of the no-parking zone in the target area, and the movement routes of mobile bodies 1 in the target area. In (b) in FIG. 3, the upper graph illustrates the state transition of a robot (mobile body 1), and the lower graph illustrates constraint violation degree. The constraint violation degree indicates the degree to which the state of an object (mobile body 1) deviates from the allowable range. The example illustrated in (b) in FIG. 3 shows that the constraint violation degree increases during the shaded time period because the robot is stopped in the no-parking zone during the time period.

As illustrated in (a) in FIG. 3, in the determination method in the comparative example, whether the constraint condition is satisfied is determined by a series of processes including the process of searching for mobile body 1 in a stopped state, the process of determining whether mobile body 1 in the stopped state is present in the no-parking zone, and the process of determining whether a duration for which mobile body 1 is stopped in the no-parking zone is more than or equal to a predetermined time, which are described in the form of a program. Describing the process of determining whether the constraint condition is satisfied in the form of a program has no problem in the case where the number of conditions included in the constraint condition is small. However, as the number of conditions included in the constraint condition increases, the description for the process of the determination tends to be problematically complicated because every condition has to be described in the form of a program. Furthermore, in this case, as the number of conditions included in the constraint condition increases, the possibility that the process of the determination includes a description error problematically increases.

In contrast, in the method for the determination using the temporal logic expression, as illustrated in (b) in FIG. 3, even when the number of conditions included in the constraint condition is large, it is only required to change, for each condition, the allowable range, the state of the object, and the penalty value, which are referred to in the temporal logic expression. Accordingly, the method for the determination using the temporal logic expression has such an advantage that the process of the determination is easy to describe and is less likely to include a description error.

Conditions subject to determination using the temporal logic expression shown in FIG. 2 will be described below. Note that the first condition to the ninth condition described below are an example of conditions included in the constraint condition. Information processing system 100 according to the embodiment need not execute a simulation in which all of the first condition to the ninth condition are included in the constraint condition. In addition, information processing system 100 according to the embodiment may execute a simulation in which a condition other than the first condition to the ninth condition is included in the constraint condition.

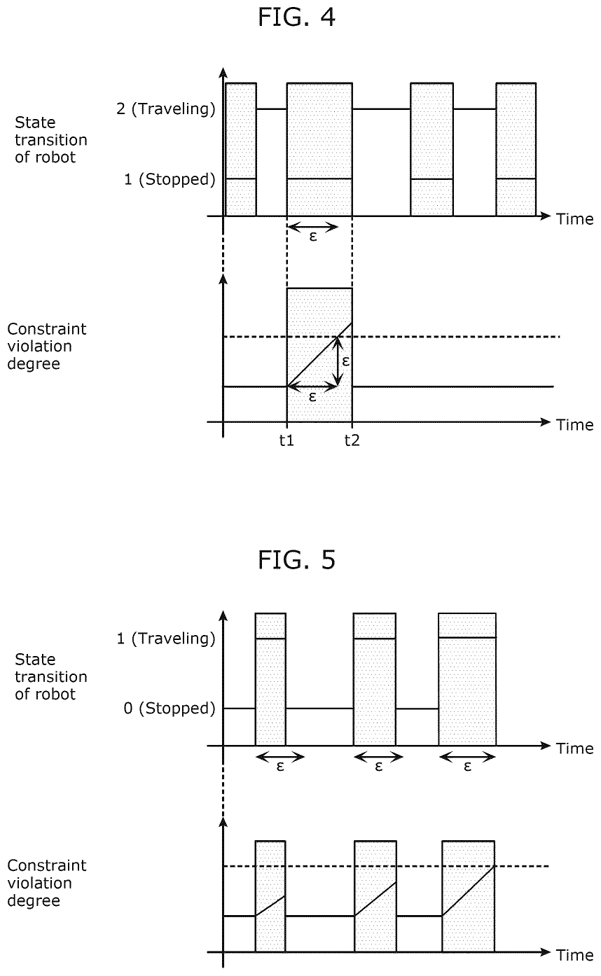

FIG. 4 is an explanatory diagram of the first condition. The first condition is a condition that mobile body 1 is forbidden to be stopped in the no-parking zone for a long time. The first condition corresponds to a condition regarding the movement or stop of mobile body 1 in a predetermined zone or during a predetermined time period. The purpose of the first condition is to prevent mobile body 1 from committing a parking violation. In FIG. 4, the upper graph illustrates the state transition of a robot (mobile body 1), and the lower graph illustrates the constraint violation degree. The state of the robot indicates “1” when the robot is stopped and indicates “2” when the robot is traveling.

In a temporal logic expression used in the determination of the first condition, “ε” denotes an allowable stop duration, “φ” denotes a function that outputs “1” when the robot is stopped, and “Area” denotes a function that accumulates an exceeding parking time “here, ‘[−ε, 0]φ=1,’ that is, always as long as the robot is stopped (φ=1) beyond duration & for which the parking is allowed.” In the example illustrated in FIG. 4, while the state of the robot is “stopped” in the no-parking zone (i.e., “φ=1”), the penalty value “duration for which the robot is parked beyond duration ε” is accumulated with time, and thus, the constraint violation degree increases.

In the example illustrated in FIG. 4, the robot is stopped in the no-parking zone during a time period from time point t1 to t2. In the example illustrated in FIG. 4, when the duration for which the state of the robot is “stopped” in the no-parking zone is greater than or equal to allowed duration “ε,” the constraint violation degree becomes greater than or equal to its threshold (see a broken line in the figure), and thus, the first condition is no longer satisfied. As long as the robot is stopped beyond the threshold of the constraint violation degree, the constraint violation degree is always (“G”) accumulated by function Area. That is, in the case of FIG. 4, “t2−ε” is accumulated as the constraint violation degree.

FIG. 5 is an explanatory diagram of a second condition. The second condition is a condition that mobile body 1 is forbidden to travel for a long time. The second condition corresponds to a condition regarding the movement duration of mobile body 1. The purpose of the second condition is to prevent the remaining battery level of mobile body 1 from decreasing to zero. In FIG. 5, the upper graph illustrates the state transition of a robot (mobile body 1), and the lower graph illustrates the constraint violation degree. The state of the robot indicates “0” when the robot is stopped at a base and charged and indicates “1” when the robot is traveling (or temporarily stopped between runs) after leaving the base.

In a temporal logic expression used in the determination of the second condition, “ε” denotes a duration for which the robot that is allowed to travel on a single battery charge (e.g., 180 minutes), and “φ” denotes a function that outputs “1” while the robot is traveling. In addition, “Area” denotes a function that always accumulates a value increasing in proportion to time from 0 to 1.5 times the value of “ε” (the critical traveling duration of the robot), up to the retrieval cost (e.g., 20000 yen) of the robot in the case where the remaining battery level decreases to zero.

In the example illustrated in FIG. 5, while the state of the robot is “traveling” (i.e., “φ=1”), the penalty value is accumulated with time, and thus, the constraint violation degree increases. In addition, the constraint violation degree is reset when the state of the robot turns to “stopped” (i.e., “φ=0”). In the example illustrated in FIG. 5, when the duration for which the state of the robot is “traveling” is greater than or equal to allowed duration “ε,” the constraint violation degree becomes greater than or equal to its threshold (see a broken line in the figure), and thus, the second condition is no longer satisfied. The lower graph in FIG. 5 illustrates an example in which the constraint violation degree is not accumulated because the robot is stopped and charged within the time indicated by “ε” after the robot is charged.

FIG. 6 is an explanatory diagram of a third condition. The third condition is a condition that mobile body 1 is forbidden to travel in a predetermined time period. The third condition corresponds to the condition regarding the movement or stop of mobile body 1 in the predetermined zone or during the predetermined time period. The purpose of the third condition is to prevent mobile body 1 from committing a traffic violation. In FIG. 6, the upper graph illustrates the state transition of a robot (mobile body 1), and the lower graph illustrates the constraint violation degree. The state of the robot indicates “0” when the robot is stopped and indicates “1” when the robot is traveling.

In a temporal logic expression used in the determination of the third condition, “ε” is “0,” and “φ” denotes a function that outputs “1” while the robot is traveling. In addition, “Area” denotes a function that adds a fine for a violation of traffic distribution (e.g., 6000 yen) if the robot travels in a time period during which the robot is forbidden to travel (e.g., a time period of a pedestrian mall)

In the example illustrated in FIG. 6, the robot travels in the time period during which the robot is forbidden to travel, from time period t3 to t4, causing the constraint violation degree to reach its threshold (see a broken line in the figure), and thus, the third condition is no longer satisfied.

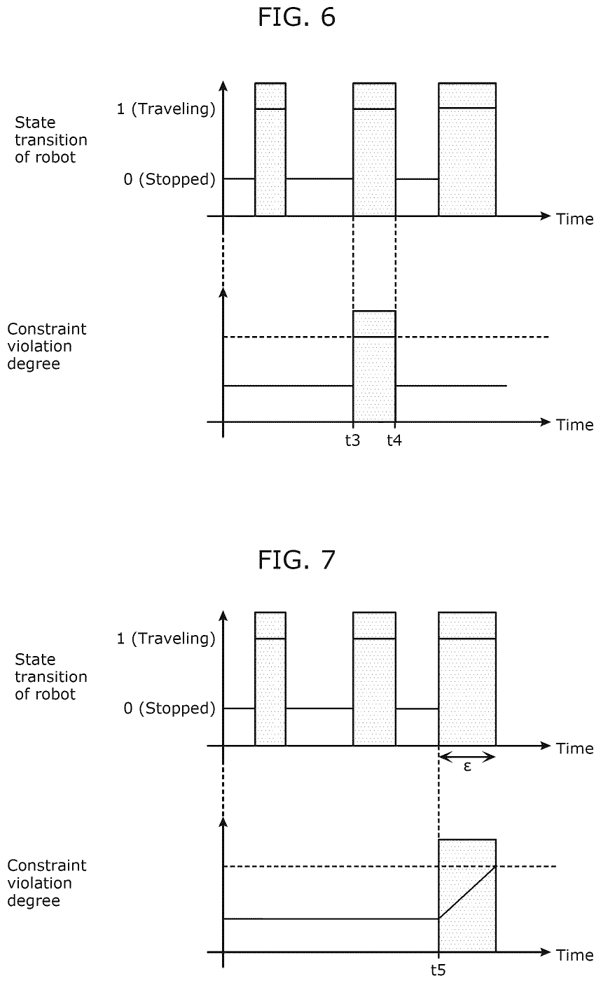

FIG. 7 is an explanatory diagram of a fourth condition. The fourth condition is a condition that mobile body 1 is forbidden to travel after a predetermined time point. The fourth condition corresponds to the condition regarding the movement or stop of mobile body 1 in the predetermined zone or during the predetermined time period. The purpose of the fourth condition is to prevent mobile body 1 from causing an accident while traveling in the nighttime. In FIG. 7, the upper graph illustrates the state transition of a robot (mobile body 1), and the lower graph illustrates the constraint violation degree. The state of the robot indicates “0” when the robot is stopped and indicates “1” when the robot is traveling.

In a temporal logic expression used in the determination of the fourth condition, “ε” denotes a time period after a sunset time point (predetermined time point) during which a camera installed on the robot cannot detect an object near the robot (e.g., 30 minutes), and “φ” denotes a function that outputs “1” while the robot is traveling. In addition, “Area” denotes a function that accumulates the penalty value increasing in proportion to time from the sunset time point until when the environmental illuminance around the robot becomes 0 lx (e.g., 90 minutes), up to the retrieval cost (e.g., 20000 yen) of the robot in the case where the robot becomes undrivable.

In the example illustrated in FIG. 7, while the state of the robot is “traveling” (i.e., “φ=1”) after time point t5, the predetermined time point, the penalty value is accumulated with time, and thus, the constraint violation degree increases. In the example illustrated in FIG. 7, when the duration for which the state of the robot is “traveling” is greater than or equal to allowed duration “ε,” the constraint violation degree becomes greater than or equal to its threshold (see a broken line in the figure), and thus, the fourth condition is no longer satisfied.

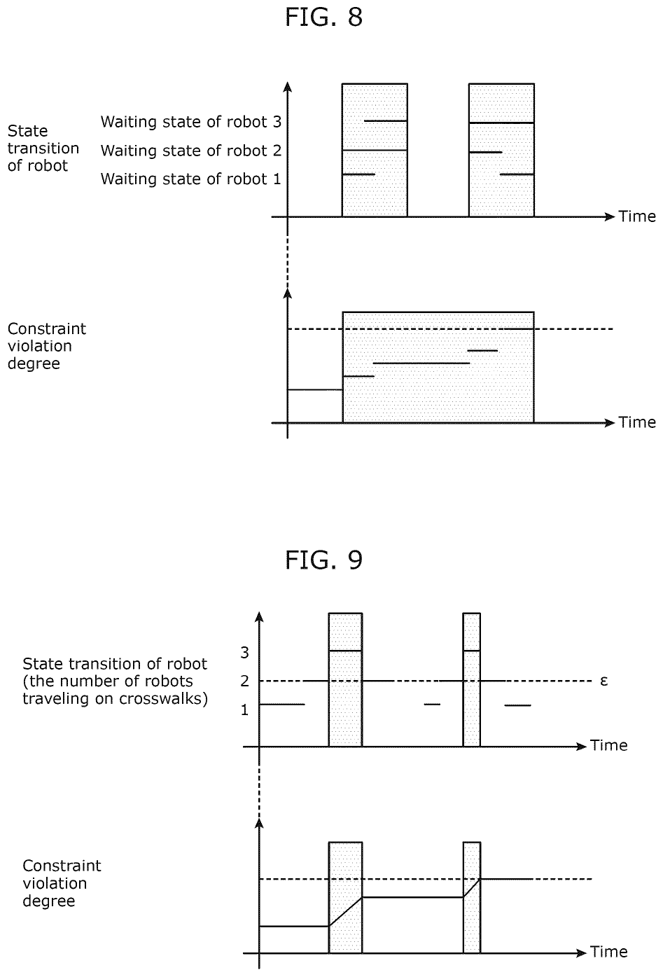

FIG. 8 is an explanatory diagram of a fifth condition. The fifth condition is a condition that a plurality of mobile bodies 1 are forbidden to depart from or arrive at the base simultaneously. The fifth condition corresponds to a condition regarding the movement with respect to the base of mobile body 1. The purpose of the fifth condition is to make the operation of mobile bodies 1 efficient at the base. In FIG. 8, the upper graph illustrates the state transitions of a plurality of (here, three) robots (mobile bodies 1), and the lower graph illustrates the constraint violation degree. The state of each robot indicates a significant value when the robot is waiting at a base and indicates “0” when the robot has left the base.

In a temporal logic expression used in the determination of the fifth condition, “ε” denotes the number of robots allowed to wait at the base (here, one), “φ” denotes a function that outputs a fee (here, an express delivery fee) to be refunded to a customer when the delivery of a delivery item is delayed in the case where the number of waiting robots exceeds the number indicated by “ε.” In addition, “Area” denotes a function that always adds the penalty value.

In the example illustrated in FIG. 8, the constraint violation degree is incremented whenever the duration for which the allowed number or more of robots wait at the base exceeds the predetermined time. In the example illustrated in FIG. 8, when the constraint violation degree reaches its threshold (see a broken line in the figure), and thus, the fifth condition is no longer satisfied.

FIG. 9 is an explanatory diagram of a sixth condition. The sixth condition is a condition that a predetermined number of mobile bodies 1 or more are forbidden to move simultaneously on one or more crosswalks. The sixth condition corresponds to a condition regarding an operator that remotely controls mobile body 1. The purpose of the sixth condition is intended to make the remote control of mobile body 1 by the operator efficient on the one or more crosswalks. In FIG. 9, the upper graph illustrates the state transition of a robot (mobile body 1), and the lower graph illustrates the constraint violation degree. The state of the robot changes in accordance with the number of robots that are traveling on any one of the one or more crosswalks.

In a temporal logic expression used in the determination of the sixth condition, “ε” denotes the number of operators simultaneously operative (here, two), “φ” denotes a function that outputs “1” when the number of robots traveling on any one of the one or more crosswalks exceeds the value indicated by “ε,” and “Area” denotes a function that always accumulates the value that is the number of robots moving on any one of the one or more crosswalks under the condition “φ=1.”

In the example illustrated in FIG. 9, if the number of robots traveling on any one of one or more crosswalks exceeds two, the penalty value is accumulated with time, and thus, the constraint violation degree increases. In the example illustrated in FIG. 9, when the constraint violation degree is greater than or equal to its threshold (see a broken line in the figure), and thus, the sixth condition is no longer satisfied.

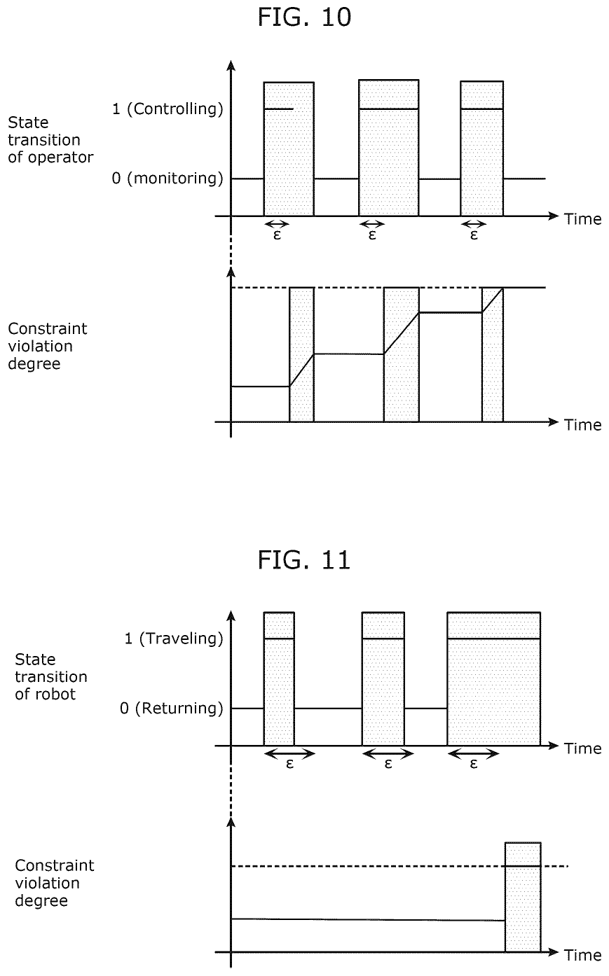

FIG. 10 is an explanatory diagram of a seventh condition. The seventh condition is a condition that an operator is forbidden to continue remote control beyond a predetermined time. The seventh condition corresponds to a condition regarding an operator that remotely controls mobile body 1. The purpose of the seventh condition is to prevent the operator from committing a violation of a labor standards law. In FIG. 10, the upper graph illustrates the state transition of the operator, and the lower graph illustrates the constraint violation degree. The state of the operator indicates “1” when the robot is remotely controlled and indicates “0” when the robot is remotely monitored.

In a temporal logic expression used in the determination of the seventh condition, “ε” denotes a duration for which the operator can continue the remote control, “φ” denotes a function that outputs “1” when the operator continues the remote control beyond the time indicated by “ε” and “Area” denotes a function that always accumulates this value.

In the example illustrated in FIG. 10, when the duration for which the operator continues the remote control exceeds “ε,” the predetermined time, the penalty value is always accumulated with time, and the constraint violation degree increases. In the example illustrated in FIG. 10, when the constraint violation degree is greater than or equal to its threshold (see a broken line in the figure), and thus, the seventh condition is no longer satisfied.

FIG. 11 is an explanatory diagram of an eighth condition. The eighth condition is a condition that mobile body 1 is forbidden to carry a delivery item beyond a predetermined range with respect to the base. The eighth condition corresponds to the condition regarding the movement with respect to the base of mobile body 1. The purpose of the eighth condition is to set an area that allows an order from a customer to be received within the range within which a delivery item can be carried. In FIG. 11, the upper graph illustrates the state transition of a robot (mobile body 1), and the lower graph illustrates the constraint violation degree. The state of the robot indicates “0” when the robot is returning to the base and indicates “1” when the robot is traveling (or temporarily stopped between runs) after leaving the base.

In a temporal logic expression used in the determination of the eighth condition, “ε” denotes a time allowed for the robot to return to the base after departing the base (e.g., 60 minutes), “φ” denotes a function that outputs “1” or a delay duration when the robot travels beyond the time indicated by “ε,” and “Area” denotes a function that always adds this value.

In the example illustrated in FIG. 11, the constraint violation degree is incremented whenever the duration for which the robot travels exceeds “ε,” the predetermined time. In the example illustrated in FIG. 11, when the constraint violation degree reaches its threshold (see a broken line in the figure), and thus, the eighth condition is no longer satisfied.

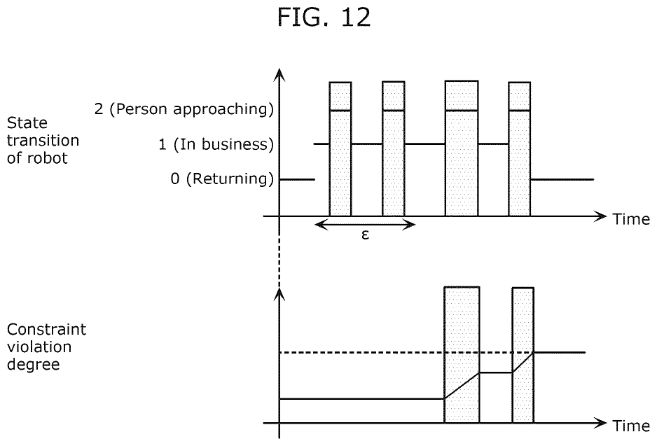

FIG. 12 is an explanatory diagram of the ninth condition. The ninth condition is a condition that mobile body 1 that performs mobile vending of commercial products is forbidden to move in the state where the commercial products are out of stock. The ninth condition corresponds to a condition regarding the stock of a delivery item to be carried by mobile body 1. The purpose of the ninth condition is to prevent a loss of the opportunity to sell commercial products in mobile vending. In FIG. 12, the upper graph illustrates the state transition of a robot (mobile body 1), and the lower graph illustrates the constraint violation degree. The state of the robot indicates “0” when the robot is returning to the base, indicates “1” when the robot is in business, performing the mobile vending after leaving the base, and indicates “2” when a person is approaching the robot.

In a temporal logic expression used in the determination of the ninth condition, “ε” denotes a mean predicted time from when the robot departs the base until when the commercial products are out of stock (e.g., 240 minutes), “φ” denotes a function that outputs “1” when a person approaches the robot in the state where the commercial products are out of stock, and “Area” denotes a function that always accumulates this value.

In the example illustrated in FIG. 12, when a person approaches the robot in the state where the commercial products are out of stock, the penalty value is accumulated with time, and thus, the constraint violation degree increases. In the example illustrated in FIG. 12, when the constraint violation degree is greater than or equal to its threshold (see a broken line in the figure), and thus, the ninth condition is no longer satisfied.

### 3. Operation

The operation of information processing system 100 according to the embodiment will be described below.

### 3-1. Basic Operation Example

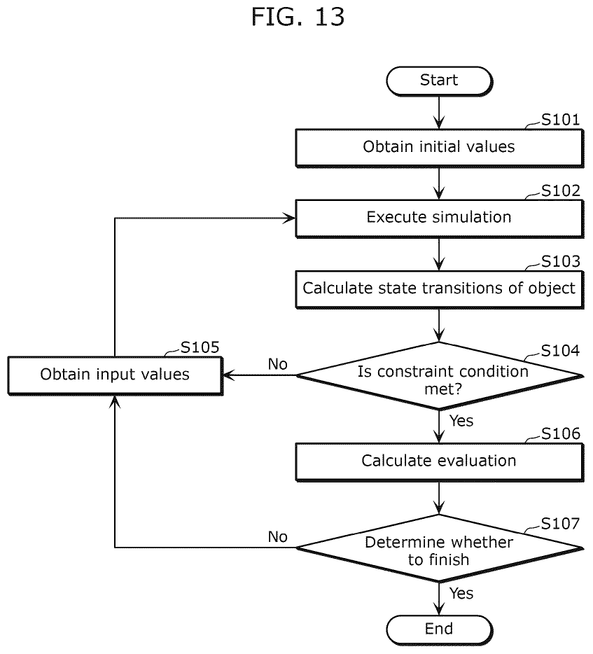

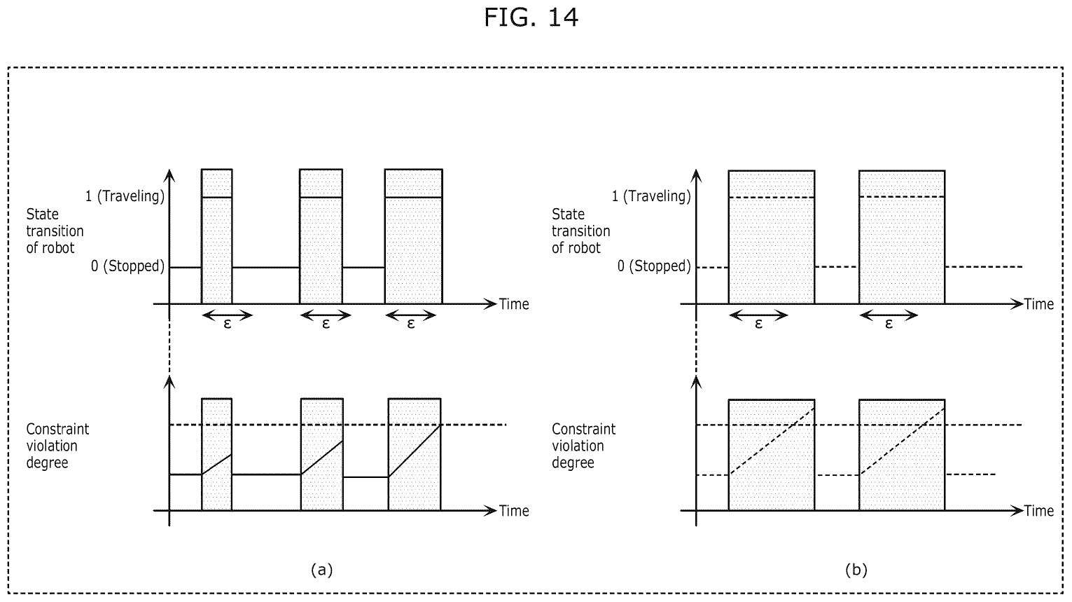

First, the basic operation of information processing system 100 according to the embodiment (in other words, the basic method of the information processing method) will be described with reference to FIG. 13. FIG. 13 is a flowchart illustrating the basic operation example of information processing system 100 according to the embodiment.

As illustrated in FIG. 13, information processing system 100 first obtains the initial values of the operation parameters of mobile body 1 (S101). Specifically, the user makes the initial setting by inputting the operation parameter of mobile body 1 to be used in the simulation, watching, for example, the input screen displayed on outputter 22 of information processing terminal 200. Accordingly, information processing system 100 obtains the initial values of the operation parameters of mobile body 1 that are input into information processing terminal 200.

Information processing system 100 next executes the simulation (S102). Specifically, information processing system 100 executes the simulation according to the operation parameters of mobile body 1 obtained by the user making the initial setting.

Information processing system 100 next calculates transitions of the state of an object in the simulation based on the execution result of the simulation (S103). Specifically, in the case where the constraint condition includes one or more conditions, information processing system 100 calculates transitions of the state of an object being a determination target (e.g., mobile body 1 or an operator) for each of the conditions.

Information processing system 100 next determines whether the constraint condition is met, based on the calculated transitions of the state of the object (S104). Specifically, in the case where the constraint condition includes one or more conditions, information processing system 100 determines, for each of the conditions, whether the condition is met, using the corresponding temporal logic expression.

Here, for example, in the determination using the temporal logic expression in step S104, information processing system 100 may cause outputter 22 of information processing terminal 200 to display a screen that shows the correlation between the transitions of the state of the object and the constraint violation degree for each condition. FIG. 14 is a diagram illustrating an example of the screen showing the correlation between the transitions of the state of the object and the constraint violation degree. FIG. 14 shows the correlation between the transitions of the state of the object and the constraint violation degree under the second condition. Furthermore, in FIG. 14, (a) is a diagram illustrating the case where the object is robot A (mobile body 1), and (b) is a diagram illustrating the case where the object is robot B (mobile body 1).

In this case, the user may artificially determine whether the transitions of the state of the object satisfy the constraint condition, watching the screen described above displayed on outputter 22. Note that information processing system 100 need not cause outputter 22 of information processing terminal 200 to display the screen described above.

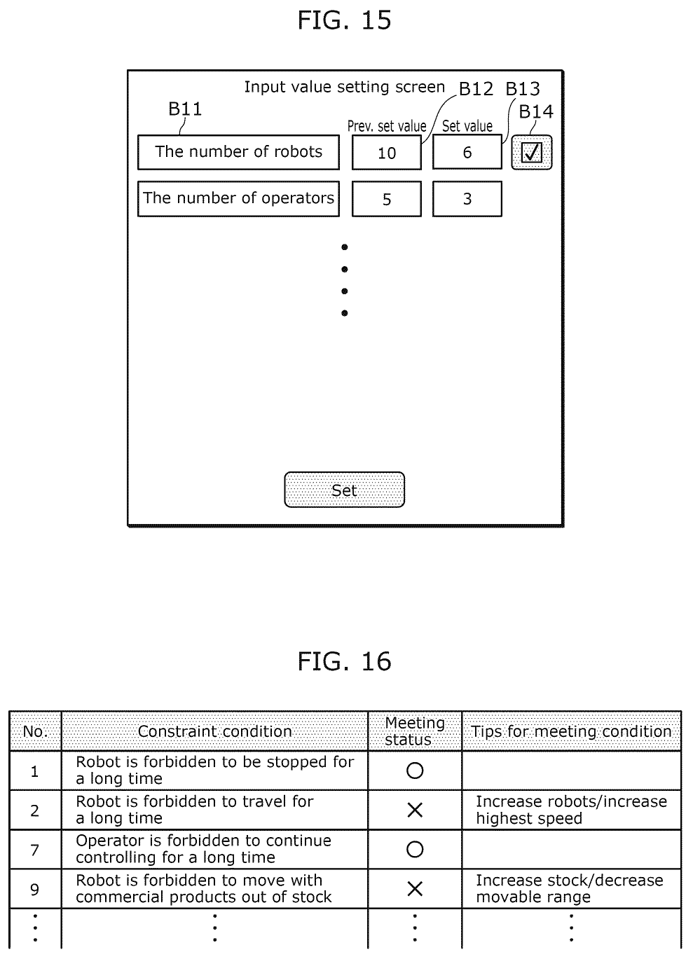

Referring back to FIG. 13, when at least one of the conditions of the constraint condition is not met (S104: No), information processing system 100 obtains an input value that corrects at least some of the operation parameters of mobile body 1 (S105). Specifically, information processing system 100 causes outputter 22 of information processing terminal 200 to display an input value setting screen as illustrated in FIG. 15. Then, the user makes the setting of the input value, watching the input value setting screen. Accordingly, information processing system 100 obtains the input value that is input into information processing terminal 200. Then, information processing system 100 executes steps S102 to S104 again according to the obtained input value.

FIG. 15 is a diagram illustrating an example of the input value setting screen. On the input value setting screen, first field B11, second field B12, third field B13, and fourth field B14 are displayed for each of the types of the operation parameters of mobile body 1. In first field B11, the name indicating the type of the operation parameter of mobile body 1 is displayed. In second field B12, a set value in the previous execution of the simulation is displayed. In third field B13, a set value in the next execution of the simulation can be input. In fourth field B14, the result of determining whether the set value is valid is displayed. In the example illustrated in FIG. 15, the user changes the number of robots (mobile bodies 1) from “10” to “6” and changes the number of operators from “5” to “3.”

Referring back to FIG. 13, when all the conditions included in the constraint condition are met (S104: Yes), information processing system 100 next executes the calculation to evaluate the execution result of the simulation (S106). Specifically, information processing system 100 executes the calculation to evaluate the execution result of the simulation using at least one of the safety index, the economic rationality index, or the convenience index each pertaining to the operation of mobile body 1.

Information processing system 100 next determines whether to finish the simulation (S107). Specifically, information processing system 100 determines to finish the simulation when the calculated evaluation is greater than a threshold, and determines not to finish the simulation when the calculated evaluation is not greater than the threshold. For example, information processing system 100 determines to finish the simulation when a first score indicating the evaluation based on the safety index, a second score indicating the evaluation based on the economic rationality index, and a third score indicating the evaluation based on the convenience index are greater than a first threshold, a second threshold, and a third threshold, respectively; otherwise, information processing system 100 determines not to finish the simulation.

When determining to finish the simulation (S107: Yes), information processing system 100 finishes the simulation and outputs the evaluation result of evaluating the execution result of the simulation. Specifically, information processing system 100 causes outputter 22 of information processing terminal 200 to display the result of evaluating the execution result of the simulation using at least one of the safety index, the economic rationality index, or the convenience index each pertaining to the operation of mobile body 1.

Here, for example, information processing system 100 may cause outputter 22 of information processing terminal 200 to display a screen that shows the status of whether the constraint condition is met as illustrated in FIG. 16. FIG. 16 is a diagram illustrating an example of the screen showing the status of whether the constraint condition is met. In the example illustrated in FIG. 16, for each condition, a meeting status indicating the level of condition met and tips for meeting the constraint condition are displayed.

Here, it is assumed that each condition included in the constraint condition includes a prerequisite condition that has to be met in the simulation and a recommended condition that is more stringent than the prerequisite condition and may be met. The meeting status indicates a cross when only the prerequisite condition is met, and indicates a circle when both the prerequisite condition and the recommended condition are met. When the meeting status indicates a cross, the tips show how to set the operation parameters of mobile body 1 to meet the recommended condition. Watching the screen, the user may determine to simply finish the simulation or may determine to execute the simulation again after changing the operation parameters of mobile body 1.

Note that the tips may be prepared in advance by the designer of the system or may be automatically generated by information processing system 100 comparing the values of operation parameters before and after the execution of the simulation. That is, in the case where it is found that the recommended condition is not met when the simulation is executed with a relatively small number of robots, while the constraint condition (e.g., the second condition) is satisfied by executing the simulation with a relatively large number of robots, information processing system 100 may automatically generate and present “Increase the number of robots” as tips for meeting the recommended condition. That is, information processing system 100 may cause outputter 22 of information processing terminal 200 to display findings obtained from a sensibility analysis of the operation parameters.

Note that information processing system 100 may cause outputter 22 of information processing terminal 200 to display the screen showing the status of whether the constraint condition is met after executing step S104.

Referring back to FIG. 13, when determining not to finish the simulation (S107: No), information processing system 100 executes steps S102 to S107 again.

### 3-2. First Operation Example

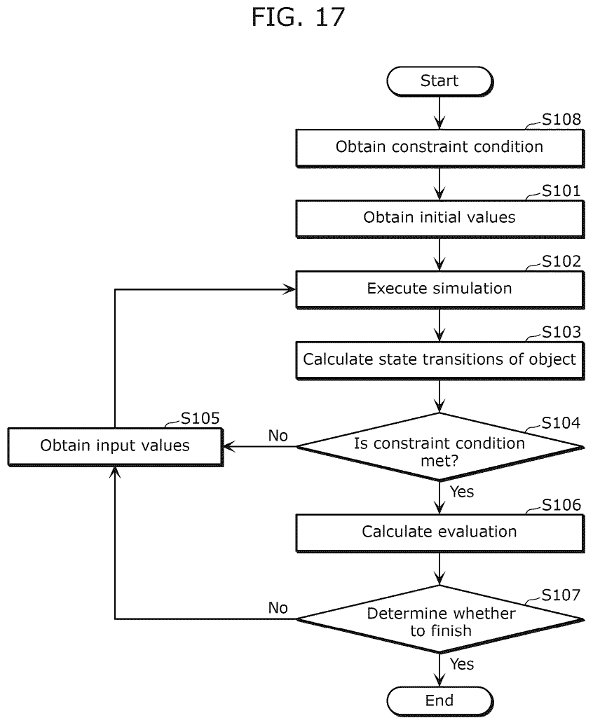

Next, the first operation example of information processing system 100 according to the embodiment will be described below with reference to FIG. 17. FIG. 17 is a flowchart illustrating the first operation example of information processing system 100 according to the embodiment. Note that the first operation example is the same as the basic operation example except for step S108. Thus, the description of the common points will be omitted here.

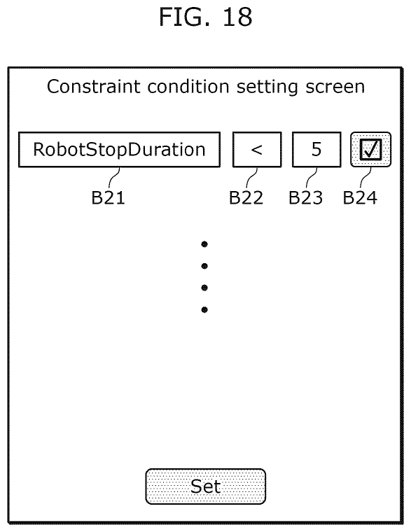

The first operation example differs from the basic operation example in that information processing system 100 executes step S108 before executing step S101. In the first operation example, information processing system 100 obtains the constraint condition specified by the user before obtaining the initial values (S108). In other words, in the first operation example, information processing system 100 obtains the constraint condition specified by the user before executing the simulation. Specifically, information processing system 100 causes outputter 22 of information processing terminal 200 to display a constraint condition setting screen as illustrated in FIG. 18. Then, the user makes the setting of the constraint condition, watching the constraint condition setting screen. Accordingly, information processing system 100 obtains the constraint condition that is input into information processing terminal 200.

FIG. 18 is a diagram illustrating an example of the constraint condition setting screen. On the constraint condition setting screen, first field B21, second field B22, third field B23, and fourth field B24 are displayed for each of the conditions. In first field B21, the name indicating the type of a changeable parameter pertaining to the condition is displayed. Into second field B22, the equal sign or an inequality sign can be input. Into third field B23, a setting value that is allowable for the user under the condition can be input. In fourth field B24, the result of determining whether the set value is valid is displayed. In the example illustrated in FIG. 18, the user has set “less than five minutes” to an allowable stop duration (“RobotStopDuration”) of a robot (mobile body 1) under the first condition.

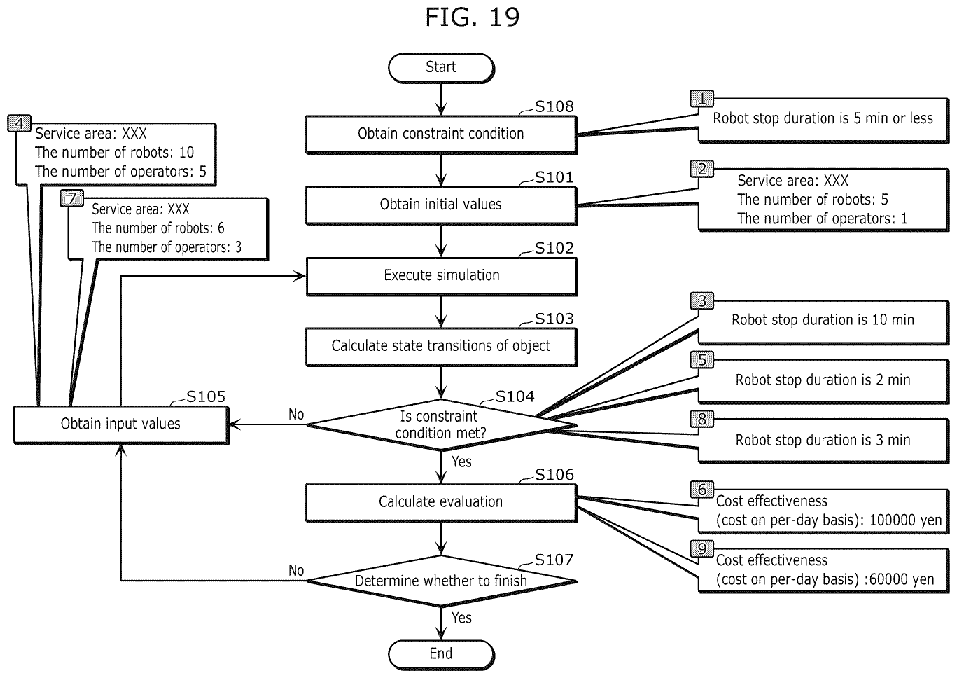

FIG. 19 is a flowchart illustrating a specific example of the first operation example of information processing system 100 according to the embodiment. Note that the flowchart illustrated in FIG. 19 is the same as the flowchart illustrated in FIG. 17 except that a plurality of balloons are illustrated. Thus, the description of the common points will be omitted here. In addition, it is assumed here that the constraint condition includes only the first condition, for ease of description.

First, in step S108, the user makes the setting of the constraint condition, and thus, information processing system 100 obtains the constraint condition. Here, as illustrated in a first balloon, information processing system 100 obtains the constraint condition that “Robot stop duration” is “5 min or less.” Next, in step S101, the user makes the initial setting, and thus, information processing system 100 obtains the initial values. Here, as illustrated in a second balloon, information processing system 100 obtains the initial values indicating that “Service area (target area)” is “XXX,” “The number of robots” is 5, and “The number of operators” is 1.

Then, in step S102, information processing system 100 executes the simulation according to the obtained initial values and, in step S103, calculates transitions of the state of an object in the simulation based on the execution result of the simulation.

Thereafter, in step S104, information processing system 100 determines whether the constraint condition is met, based on the calculated transitions of the state of the object. Here, as illustrated in a third balloon, “Robot stop duration” of any one of the robots is “10 min” in the simulation, thus not meeting the constraint condition that “Robot stop duration” is “5 min or less” (Step S104: No). As a result, information processing system 100 causes outputter 22 of information processing terminal 200 to display the input value setting screen.

In step S105, the user makes the setting of the input values, and thus, information processing system 100 obtains the input values. Here, as illustrated in a fourth balloon, information processing system 100 obtains the input values indicating that “The number of robots” is changed to 10, and “The number of operators” is changed to 5. Then, information processing system 100 executes steps S102 to S104 again according to the obtained input value.

In step S104 executed again, as illustrated in a fifth balloon, “Robot stop duration” is “2 min” for all of the robots in the simulation, thus meeting the constraint condition that “Robot stop duration” is “5 min or less” (S104: Yes). As a result, in step S106, information processing system 100 executes the calculation to evaluate the execution result of the simulation. Here, as illustrated in a sixth balloon, information processing system 100 calculates the evaluation using the economic rationality index indicating that “cost effectiveness (cost on a per-day basis)” is 100000 yen.

Then, in step S107, information processing system 100 determines whether to finish the simulation. Here, “cost effectiveness (cost on a per-day basis),” which is the evaluation using the economic rationality index, is 100000 yen, which is not greater than (exceeds) the threshold (here, 80000 yen) (step S107: No). As a result, information processing system 100 causes outputter 22 of information processing terminal 200 to display the input value setting screen again.

In step S105 executed again, the user makes the setting of the input values, and thus, information processing system 100 obtains the input values. Here, as illustrated in a seventh balloon, information processing system 100 obtains the input values indicating that “The number of robots” is changed to 6, and “The number of operators” is changed to 3. Then, information processing system 100 executes steps S102 to S104 again according to the obtained input value.

In step S104 executed again, as illustrated in an eighth balloon, “Robot stop duration” is “3 min” for all of the robots in the simulation, thus meeting the constraint condition that “Robot stop duration” is “5 min or less” (S104: Yes). As a result, in step S106, information processing system 100 executes the calculation to evaluate the execution result of the simulation. Here, as illustrated in a ninth balloon, information processing system 100 calculates the evaluation using the economic rationality index indicating that “cost effectiveness (cost on a per-day basis)” is 60000 yen.

Then, in step S107, information processing system 100 determines whether to finish the simulation. Here, “cost effectiveness (cost on a per-day basis),” which is the evaluation using the economic rationality index, is 60000 yen, which is greater than (falls below) the threshold (step S107: Yes). As a result, information processing system 100 finishes the simulation and outputs the evaluation result of evaluating the execution result of the simulation.

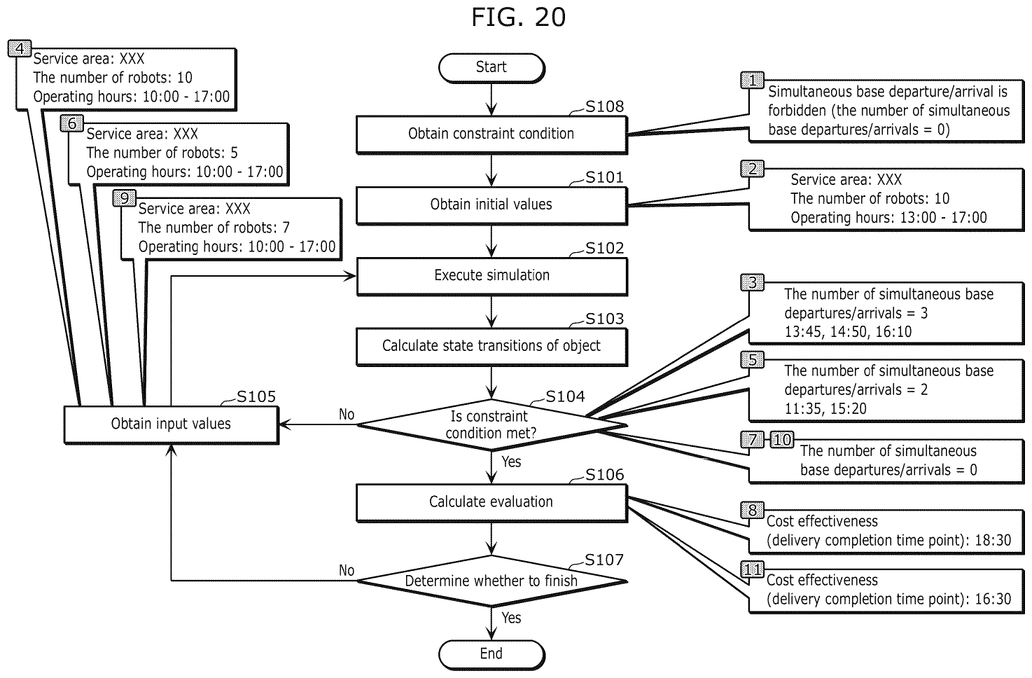

FIG. 20 is a flowchart illustrating another specific example of the first operation example of information processing system 100 according to the embodiment. Note that the flowchart illustrated in FIG. 20 is the same as the flowchart illustrated in FIG. 17 except that a plurality of balloons are illustrated. Thus, the description of the common points will be omitted here. In addition, it is assumed here that the constraint condition includes only the fifth condition, for ease of description.

First, in step S108, the user makes the setting of the constraint condition, and thus, information processing system 100 obtains the constraint condition. Here, as illustrated in a first balloon, information processing system 100 obtains the constraint condition that “The number of simultaneous base departures/arrivals” is “0 times.” Next, in step S101, the user makes the initial setting, and thus, information processing system 100 obtains the initial values. Here, as illustrated in a second balloon, information processing system 100 obtains the initial values indicating that “Service area (target area)” is “XXX,” “The number of robots” is 10, and “Operating hours” are 13:00 to 17:00.

Then, in step S102, information processing system 100 executes the simulation according to the obtained initial values and, in step S103, calculates transitions of the state of an object in the simulation based on the execution result of the simulation. Thereafter, in step S104, information processing system 100 determines whether the constraint condition is met, based on the calculated transitions of the state of the object. Here, as illustrated in a third balloon, the number of occurrences of the simultaneous departure/arrival of a plurality of robots at the base is “three times” in total: 13:45, 14:50, and 16:10, in the simulation, thus not meeting the constraint condition that “The number of simultaneous base departures/arrivals” is “0 times” (Step S104: No). As a result, information processing system 100 causes outputter 22 of information processing terminal 200 to display the input value setting screen.

In step S105, the user makes the setting of the input values, and thus, information processing system 100 obtains the input Here, as illustrated in a fourth balloon, information values. processing system 100 obtains the input value indicating that “Operating hours” are changed to 10:00 to 17:00. Then, information processing system 100 executes steps S102 to S104 again according to the obtained input value.

In step S104 executed again, as illustrated in a fifth balloon, the number of occurrences of the simultaneous departure/arrival of a plurality of robots at the base is “two times” in total: 11:35 and 15:20, in the simulation, thus not meeting the constraint condition that “The number of simultaneous base departures/arrivals” is “0 times” (Step S104: No). As a result, information processing system 100 causes outputter 22 of information processing terminal 200 to display the input value setting screen again.

In step S105 executed again, the user makes the setting of the input values, and thus, information processing system 100 obtains the input values. Here, as illustrated in a sixth balloon, information processing system 100 obtains the input value indicating that “The number of robots” is changed to 5. Then, information processing system 100 executes steps S102 to S104 again according to the obtained input value.

In step S104 executed again, as illustrated in a seventh balloon, “The number of simultaneous base departures/arrivals” is “0 times” in the simulation, thus meeting the constraint condition that “The number of simultaneous base departures/arrivals” is “0 times” (Step S104: Yes). As a result, in step S106, information processing system 100 executes the calculation to evaluate the execution result of the simulation. Here, as illustrated in an eighth balloon, information processing system 100 calculates the evaluation using the economic rationality index indicating that “cost effectiveness (delivery completion time point)” is 18:30.

Then, in step S107, information processing system 100 determines whether to finish the simulation. Here, “cost effectiveness (delivery completion time point),” which is the evaluation using the economic rationality index, is 18:30, which is not greater than (exceeds) the threshold (here, 17:00) (step S107: No). As a result, information processing system 100 causes outputter 22 of information processing terminal 200 to display the input value setting screen again.

In step S105 executed again, the user makes the setting of the input values, and thus, information processing system 100 obtains the input values. Here, as illustrated in a ninth balloon, information processing system 100 obtains the input value indicating that “The number of robots” is changed to 7. Then, information processing system 100 executes steps S102 to S104 again according to the obtained input value.

In step S104 executed again, as illustrated in a tenth balloon, “The number of simultaneous base departures/arrivals” is “0 times” in the simulation, thus meeting the constraint condition that “The number of simultaneous base departures/arrivals” is “0 times” (Step S104: Yes). As a result, in step S106, information processing system 100 executes the calculation to evaluate the execution result of the simulation. Here, as illustrated in an eleventh balloon, information processing system 100 calculates the evaluation using the economic rationality index indicating that “cost effectiveness (delivery completion time point)” is 16:30.

Then, in step S107, information processing system 100 determines whether to finish the simulation. Here, “cost effectiveness (delivery completion time point),” which is the evaluation using the economic rationality index, is 16:30, which is greater than (falls below) the threshold (step S107: Yes). As a result, information processing system 100 finishes the simulation and outputs the evaluation result of evaluating the execution result of the simulation.

### 3-3. Second Operation Example

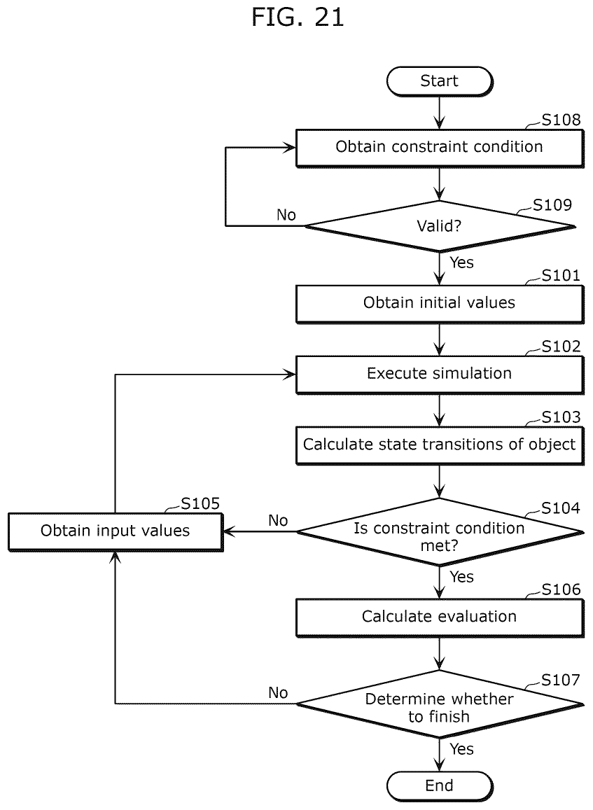

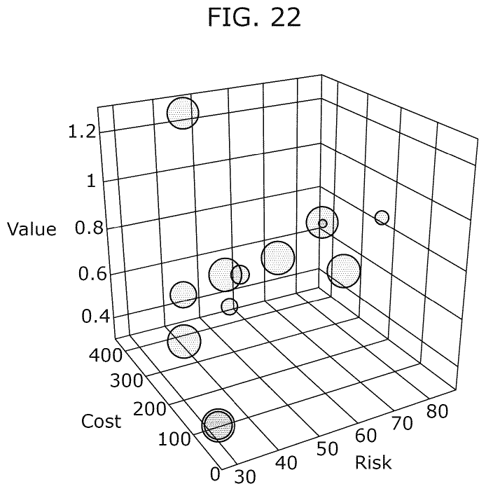

Next, the second operation example of information processing system 100 according to the embodiment will be described below with reference to FIG. 21. FIG. 21 is a flowchart illustrating the second operation example of information processing system 100 according to the embodiment. Note that the second operation example is the same as the first operation example except for step S109. Thus, the description of the common points will be omitted here.

The second operation example differs from the first operation example in that information processing system 100 executes step S109 before executing step S101. In the second operation example, information processing system 100 determines whether the obtained constraint condition is valid before obtaining the initial values (S109). Specifically, information processing system 100 causes outputter 22 of information processing terminal 200 to display a screen for the user to verify whether the obtained constraint condition is valid. Then, watching the screen, the user verifies whether the constraint condition is valid. For example, the screen displays a temporal logic expression according to the constraint condition set on the constraint condition setting screen, and the user verifies whether the temporal logic expression is correctly described.

When the result of the verification by the user shows that the temporal logic expression is correctly described, the user operates information processing terminal 200 to make an input indicating that the constraint condition is valid. Accordingly, information processing system 100 determines that the obtained constraint condition is valid (S109: Yes) and executes subsequent steps S101 to S107. On the other hand, when the temporal logic expression is not correctly described, the user operates information processing terminal 200 to make an input indicating that the constraint condition is not valid. Accordingly, information processing system 100 determines that the obtained constraint condition is invalid (S109: No) and executes S108 again.

Note that step S109 may be executed in step S107. In this case, as illustrated in FIG. 22 for example, information processing system 100 may cause outputter 22 of information processing terminal 200 to display a screen that shows the level of the constraint condition met in the simulation, together with the evaluation of the execution result of the simulation.

FIG. 22 is a diagram illustrating an example of the screen for verifying whether the constraint condition is valid. As illustrated in FIG. 22, the screen displays a three-dimensional graph of which the axes represent the evaluation based on the safety (Risk) index pertaining to the operation of mobile body 1, the evaluation based on the economic rationality (Cost) index pertaining to the operation of mobile body 1, and the evaluation based on the convenience (Value) index pertaining to the operation of mobile body 1. The points shown in FIG. 22 represent evaluations of the execution results of the simulation. The size of each point illustrated in FIG. 22 shows the level of the constraint condition met in the simulation. Here, the larger the size of the point, the more the constraint condition is given leeway while the prerequisite conditions of the constraint condition are satisfied. On the other hand, the smaller the size of the point, the less the constraint condition is given leeway although the prerequisite conditions of the constraint condition are satisfied.

Note that each point may be configured such that a darker blue shade of the point shows that more leeway is given to the constraint condition while the prerequisite conditions of the constraint condition are satisfied. On the other hand, each point may be configured such that a darker red shade of the point shows that less leeway is given to the constraint condition although the prerequisite conditions of the constraint condition are satisfied. Alternatively, each point may be configured such that a darker shading of the point shows that more leeway is given to the constraint condition while the prerequisite conditions of the constraint condition are satisfied. On the other hand, each point may be configured such that a lighter shading of the point shows that less leeway is given to the constraint condition although the prerequisite conditions of the constraint condition are satisfied.

Watching the screen, the user verifies whether the constraint condition is valid. When the constraint condition is determined to be valid from the result of the verification by the user, the user operates information processing terminal 200 to make an input indicating that the constraint condition is valid. Accordingly, information processing system 100 determines that the obtained constraint condition is valid (S109: Yes) and, for example, finishes the simulation. On the other hand, when the constraint condition is determined not to be valid, the user operates information processing terminal 200 to make an input indicating that the constraint condition is not valid. Accordingly, information processing system 100 determines that the obtained constraint condition is invalid (S109: No) and, for example, executes S105.

### 3-4. Third Operation Example

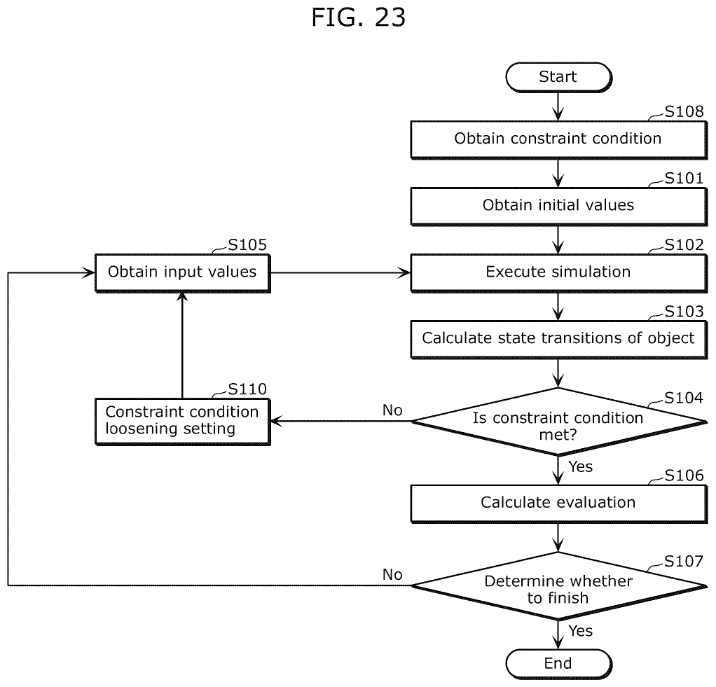

Next, the third operation example of information processing system 100 according to the embodiment will be described below with reference to FIG. 23. FIG. 23 is a flowchart illustrating the third operation example of information processing system 100 according to the embodiment. Note that the third operation example is the same as the first operation example except for step S110. Thus, the description of the common points will be omitted here.

The third operation example differs from the first operation example in that information processing system 100 executes step S110 before executing step S105 when at least one of the conditions of the constraint condition is not met (S104: No). Specifically, when the constraint condition is not satisfied, information processing system 100 executes loosening setting to loosen at least part of the constraint condition such that all of the conditions included in the constraint condition can be met in the simulation (S110).

For example, when a given condition included in the constraint condition is not met, information processing system 100 loosens the condition such that the condition can be met, and causes outputter 22 of information processing terminal 200 to display the loosened condition. For example, the loosened condition may be displayed on the input value setting screen. In this case, the user can make the setting of an input value while referring to the loosened condition displayed on the input value setting screen, and it becomes easier for the user to determine how much the constraint condition should be loosened in order for the constraint condition to be met.

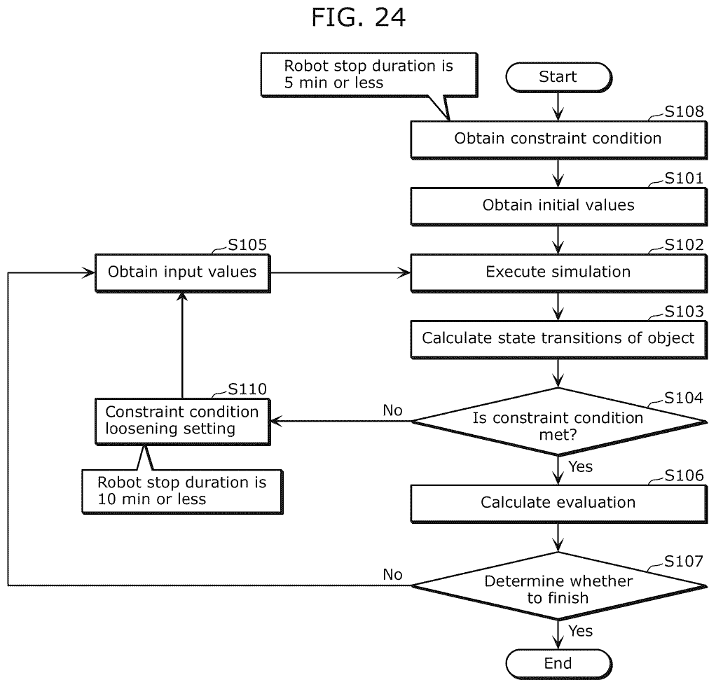

FIG. 24 is a flowchart illustrating a specific example of the third operation example of information processing system 100 according to the embodiment. Note that the flowchart illustrated in FIG. 24 is the same as the flowchart illustrated in FIG. 23 except that a plurality of balloons are illustrated. Thus, the description of the common points will be omitted here. Note that the flowchart illustrated in FIG. 24 shows the case where the constraint condition includes only the first condition as in the specific example of the first operation example. Thus, the description of the common points will be omitted here.

In the example illustrated in FIG. 24, as illustrated in a balloon, information processing system 100 loosens, in step S110, the constraint condition that “Robot stop duration” is “5 min or less” such that the constraint condition is changed to the constraint condition that “Robot stop duration” is “10 min or less.” Accordingly, the user can make the setting of the input value while referring to the loosened condition.

### 3-5. Fourth Operation Example

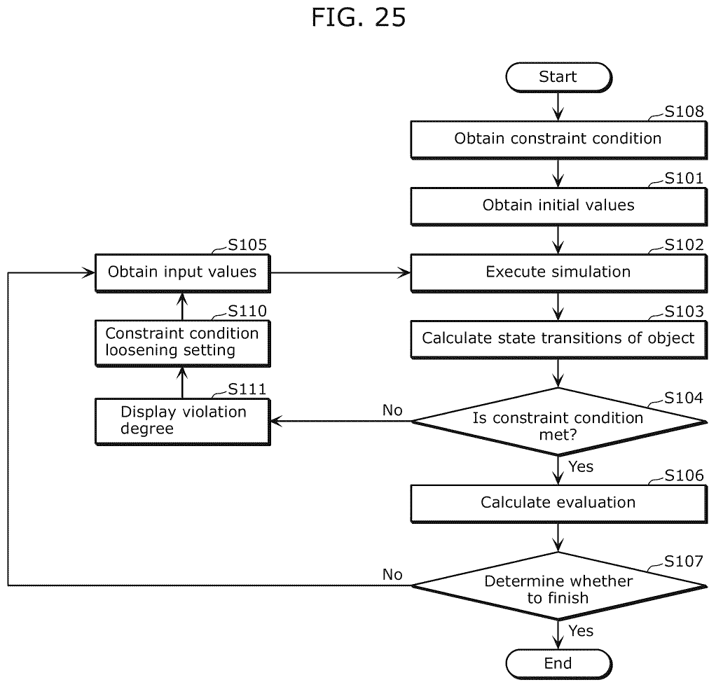

Next, the fourth operation example of information processing system 100 according to the embodiment will be described below with reference to FIG. 25. FIG. 25 is a flowchart illustrating the fourth operation example of information processing system 100 according to the embodiment. Note that the fourth operation example is the same as the third operation example except for step S111. Thus, the description of the common points will be omitted here.

The fourth operation example differs from the third operation example in that information processing system 100 executes step S111 before executing step S110. Specifically, when the constraint condition is not satisfied, information processing system 100 outputs the degree of violation of the constraint condition by calculating the violation degree pertaining to the constraint condition.

For example, when a given condition included in the constraint condition is not met, information processing system 100 calculates the violation degree pertaining to the condition. Here, the violation degree indicates the difference between the constraint violation degree that exceeds its threshold and the threshold, out of the constraint violation degrees illustrated in FIG. 4 to FIG. 12, for example. In this case, information processing system 100 refers to the calculated violation degree and can thus easily determine how much the constraint condition should be loosened in the loosening setting. Note that the calculated violation degree may be displayed on, for example, the input value setting screen. In this case, the user can make the setting of an input value while referring to the violation degree displayed on the input value setting screen, and it becomes easier for the user to determine how much the constraint condition should be loosened in order for the constraint condition to be met.

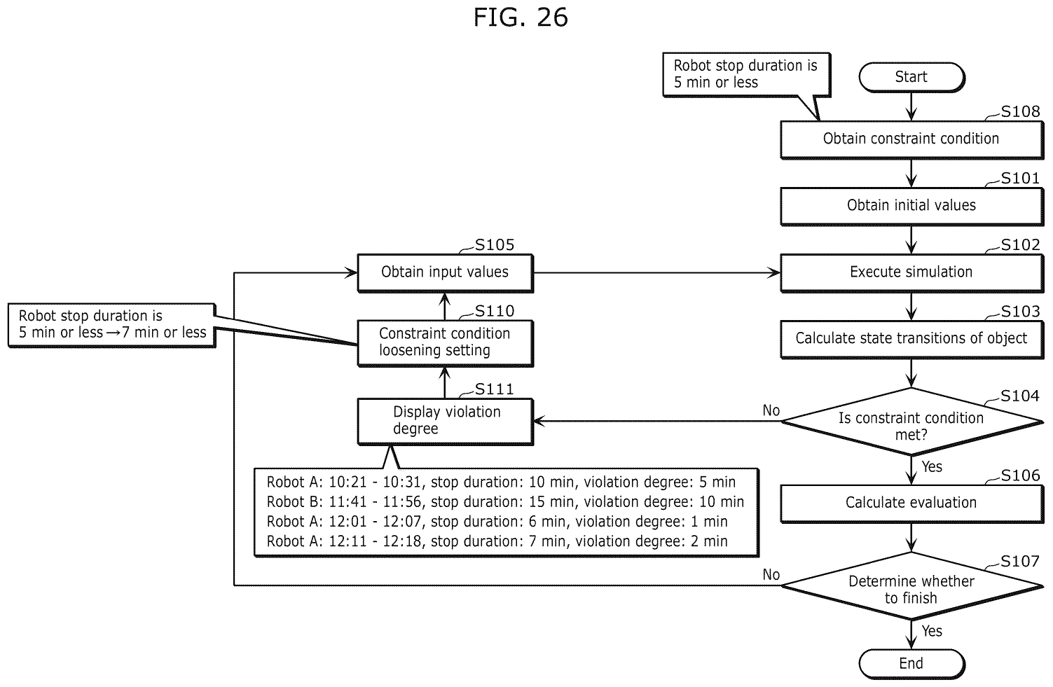

FIG. 26 is a flowchart illustrating a specific example of the fourth operation example of information processing system 100 according to the embodiment. Note that the flowchart illustrated in FIG. 26 is the same as the flowchart illustrated in FIG. 25 except that a plurality of balloons are illustrated. Thus, the description of the common points will be omitted here. Note that the flowchart illustrated in FIG. 26 shows the case where the constraint condition includes only the first condition as in the specific example of the first operation example. Thus, the description of the common points will be omitted here.

In the example illustrated in FIG. 26, as illustrated in a balloon, information processing system 100 calculates, in step S111, violation degrees in time periods in which the stop durations of robots exceed “Robot stop duration” indicated by the constraint condition. Accordingly, information processing system 100 can make the loosening setting while referring to the violation degrees. Here, as illustrated in a balloon, information processing system 100 loosens the constraint condition that “Robot stop duration” is “5 min or less” such that the constraint condition is changed to the constraint condition that “Robot stop duration” is “7 min or less.” In addition, the user can make the setting of the input value while referring to the violation degrees.

### 3-6. Fifth Operation Example

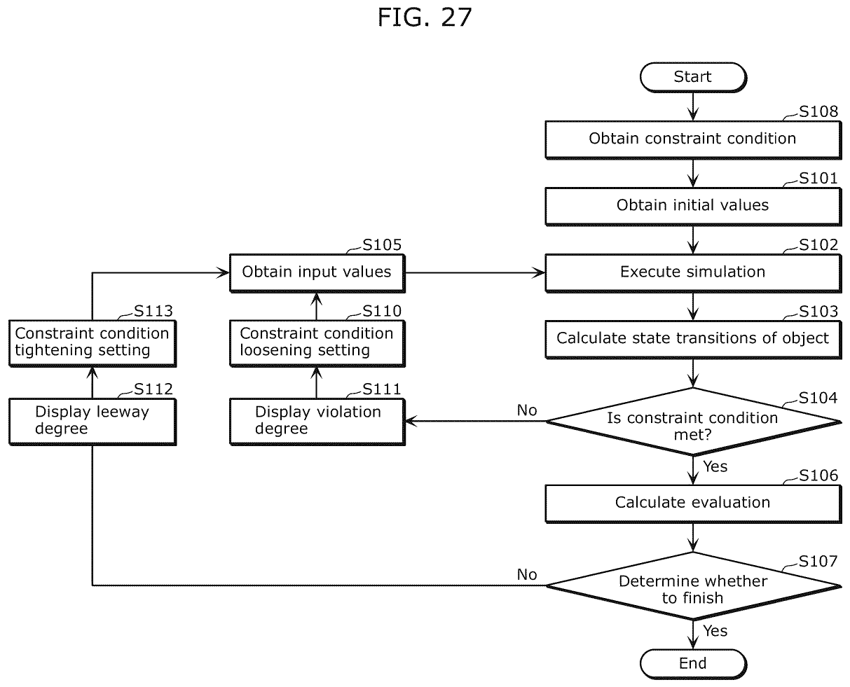

Next, the fifth operation example of information processing system 100 according to the embodiment will be described below with reference to FIG. 27. FIG. 27 is a flowchart illustrating the fifth operation example of information processing system 100 according to the embodiment. Note that the fifth operation example is the same as the fourth operation example except for steps S112 and S113. Thus, the description of the common points will be omitted here.

The fifth operation example differs from the fourth operation example in that, when determining not to finish the simulation (S107: No), information processing system 100 executes steps S112 and S113 before executing step S105. Specifically, when the evaluation result of evaluating the execution result of the simulation does not satisfy a predetermined condition (here, the calculated evaluation is not greater than the threshold), information processing system 100 outputs the degree of leeway of the constraint condition by calculating the leeway degree pertaining to the constraint condition. Here, the leeway degree indicates the difference between the constraint violation degree that does not exceed its threshold and the threshold, out of the constraint violation degrees illustrated in FIG. 4 to FIG. 12, for example. In this case, information processing system 100 refers to the calculated leeway degree and can thus easily determine how much the constraint condition should be tightened in tightening setting, which will be described later. Note that the calculated leeway degree may be displayed on, for example, the input value setting screen. In this case, the user can make the setting of an input value while referring to the leeway degree displayed on the input value setting screen, and it becomes easier for the user to determine how much the constraint condition should be tightened in order for the evaluation result to satisfy the predetermined condition.

When the evaluation result of evaluating the execution result of the simulation does not satisfy the predetermined condition, information processing system 100 executes the tightening setting in which at least part of the constraint condition is tightened such that the evaluation result can satisfy the predetermined condition (S113). For example, out of one or more conditions included in the constraint condition, information processing system 100 tightens a condition in which the corresponding constraint violation degree has leeway to reach its threshold, and information processing system 100 causes outputter 22 of information processing terminal 200 to display the tightened condition. For example, the tightened condition may be displayed on the input value setting screen. In this case, the user can make the setting of an input value while referring to the tightened condition displayed on the input value setting screen, and it becomes easier for the user to determine how much the constraint condition should be tightened in order for the evaluation result to satisfy the predetermined condition.

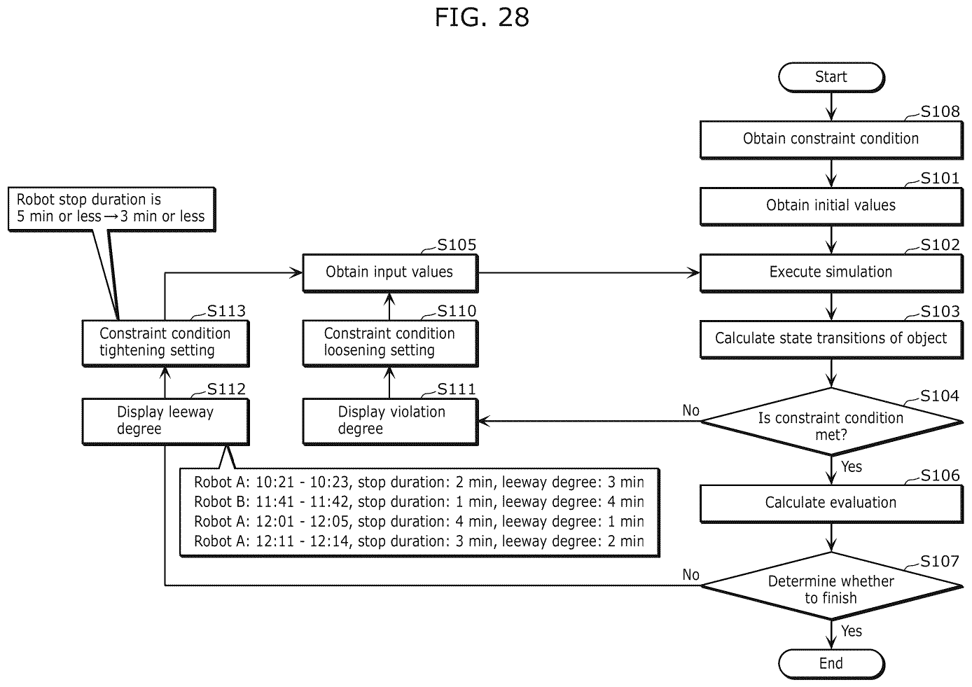

FIG. 28 is a flowchart illustrating a specific example of the fifth operation example of information processing system 100 according to the embodiment. Note that the flowchart illustrated in FIG. 28 is the same as the flowchart illustrated in FIG. 27 except that a plurality of balloons are illustrated. Thus, the description of the common points will be omitted here. Note that the flowchart illustrated in FIG. 28 shows the case where the constraint condition includes only the first condition as in the specific example of the first operation example. Thus, the description of the common points will be omitted here.

In the example illustrated in FIG. 28, as illustrated in a balloon, information processing system 100 calculates, in step S112, leeway degrees in time periods in which the stop durations of robots have leeway to reach “Robot stop duration” indicated by the constraint condition. Accordingly, information processing system 100 can make the tightening setting while referring to the leeway degrees. Here, as illustrated in a balloon, information processing system 100 tightens the constraint condition that “Robot stop duration” is “5 min or less” such that the constraint condition is changed to the constraint condition that “Robot stop duration” is “3 min or less.” In addition, the user can make the setting of the input value while referring to the leeway degrees.

Note that, in the fifth operation example, when the evaluation result of evaluating the execution result of the simulation does not satisfy the predetermined condition, information processing system 100 may execute step S113 without executing step S112.

### 4. Advantages, etc.

As described above, the information processing method and information processing system 100 according to the embodiment determine whether the constraint condition is satisfied based on the transitions of the state of the object in the simulation, and when the constraint condition is satisfied, information processing system 100 outputs the evaluation result of evaluating the execution result of the simulation. Accordingly, it is possible to determine whether the constraint condition is satisfied with consideration given to not only temporal changes but also spatial changes of the object, thus bringing about such an advantage that an efficient simulation that takes into account the constraint condition is easily executed.

In addition, in the process of determining whether the constraint condition is satisfied, the information processing method and information processing system 100 according to the embodiment makes the determination based on one function that refers to the state of the object differently for each of the conditions (here, the function described using the temporal logic expression). Accordingly, the information processing method and information processing system 100 according to the embodiment are capable of executing the process of the determination to determine whether the constraint condition is satisfied, in a uniform and systematic manner, thus bringing about such an advantage that the process of the determination is easy to describe and is less likely to include a description error even when the constraint condition includes many conditions.

In addition, the information processing method and information processing system 100 according to the embodiment also has such an advantage that a common understanding is easily reached by even a plurality of persons using the simulation.

### Other Embodiments

Although the information processing method and information processing system 100 according to one or more aspects of the present disclosure have been described above based on an embodiment, the present disclosure is not limited to the embodiment. One or more aspects of the present disclosure may also include forms achieved by making various modifications to the embodiment that can be conceived by those skilled in the art, as well as forms achieved by combining constituent elements in different embodiments, without materially departing from the spirit of the present disclosure.

In the embodiment described above, information processing system 100 obtains, in step S105, the input value that the user inputs into information processing terminal 200. However, it is not limited to this. For example, in step S105, information processing system 100 may automatically determine and obtain input values that can meet the constraint condition, without depending on the input by the user.

For example, the present disclosure can be implemented as a program for causing a processor to execute steps included in the information processing method. In addition, the present disclosure can be implemented as a non-transitory computer-readable recording medium, such as a CD-ROM, having the program recorded thereon.

For example, in the case where the present disclosure is implemented with a program (software), the steps are executed by the execution of the program using the hardware resources of a computer, such as a central processing unit (CPU), a memory, and an input-output circuit. That is, the steps are executed by the CPU obtaining data from the memory, the input-output circuit, and the like to perform computation and outputting the result of the computation to the memory, the input-output circuit, and the like.

Note that in the embodiment described above, each of the constituent elements included in information processing system 100 may be configured in the form of an exclusive hardware product, or may be implemented by executing a software program suitable for the constituent element. Each of the constituent elements may be implemented by means of a program executor, such as a CPU or a processor, reading and executing the software program recorded on a recording medium such as a hard disk or a semiconductor memory.

Note that at least one or all of the functions of information processing system 100 according to the embodiment described above is typically implemented as a large-scale integrated (LSI) circuit, which is an integrated circuit (IC). These may take the form of individual chips, or may be partially or entirely packaged into a single chip. Such IC is not limited to an LSI, and thus may be implemented as a dedicated circuit or a general-purpose processor.

A field programmable gate array (FPGA) that allows for programming after the manufacture of an LSI, or a reconfigurable processor that allows for reconfiguration of the connection and the setting of circuit cells inside an LSI may be employed.

Furthermore, variations resulting from modifications to the embodiments of the present disclosure conceived by a person skilled in the art are also included in the present disclosure so long as they do not depart from the essence of the present disclosure.

### INDUSTRIAL APPLICABILITY

The present disclosure is applicable to a system that provides a mobility service.

1. An information processing method to be executed by a computer, the information processing method comprising:
executing, according to an operation parameter of a mobile body that carries a person or a delivery item, a simulation of movement of the mobile body and demand for transfer of the person or the delivery item;
calculating, based on an execution result of the simulation, a transition of a state of an object in the simulation;
determining, based on the transition, whether a constraint condition is satisfied; and
outputting, when the constraint condition is satisfied, an evaluation result of evaluating the execution result of the simulation using at least one of a safety index, an economic rationality index, or a convenience index each pertaining to at least an operation of the mobile body.

2. The information processing method according to claim 1, wherein
the constraint condition includes a plurality of conditions, and
the determining of whether the constraint condition is satisfied is performed based on one function that refers to the state of the object differently for each of the plurality of conditions.

3. The information processing method according to claim 2, wherein
the one function is described using a temporal logic expression.

4. The information processing method according to claim 1, wherein
the constraint condition includes a condition regarding movement or stop of the mobile body in a predetermined zone or during a predetermined time period.

5. The information processing method according to claim 1, wherein
the constraint condition includes a condition regarding a movement duration of the mobile body.

6. The information processing method according to claim 1, wherein
the constraint condition includes a condition regarding movement of the mobile body with respect to a base for the mobile body.

7. The information processing method according to claim 1, wherein
the constraint condition includes a condition regarding an operator that remotely controls the mobile body.

8. The information processing method according to claim 1, wherein
the constraint condition includes a condition regarding a stock of the delivery item carried by the mobile body.

9. The information processing method according to claim 1, further comprising:
obtaining, before the executing of the simulation, the constraint condition specified by a user.

10. The information processing method according to claim 1, further comprising:
loosening at least part of the constraint condition when the constraint condition is not satisfied.

11. The information processing method according to claim 1, further comprising:
outputting a degree of violation of the constraint condition when the constraint condition is not satisfied.

12. The information processing method according to claim 1, further comprising:
tightening at least part of the constraint condition when a predetermined condition is not satisfied by the evaluation result.

13. The information processing method according to claim 1, further comprising:
outputting a degree of leeway of the constraint condition when a predetermined condition is not satisfied by the evaluation result.

14. A non-transitory computer-readable recording medium having recorded thereon a program for causing a computer to execute the information processing method according to claim 1.

15. An information processing terminal comprising:
an input receiver that receives an input of the operation parameter of the mobile body; and
an outputter that outputs the execution result of the information processing method according to claim 1 executed based on the operation parameter of the mobile body received by the input receiver, wherein
the outputter outputs the evaluation result as the execution result when the constraint condition is satisfied.
